(19) United States
(12) Patent Application Publication
(10) Pub. No.: US 2025/0366009 A1
(43) Pub. Date: Nov. 27, 2025

(54) DIELECTRIC FIN STRUCTURES FOR SEMICONDUCTOR DEVICES

(71) Applicant: Taiwan Semiconductor Manufacturing Company, Ltd., Hsinchu (TW)

(72) Inventor: Tzu-Ging LIN, Kaohsiung (TW)

(73) Assignee: Taiwan Semiconductor Manufacturing Company, Ltd., Hsinchu (TW)

(21) Appl. No.: 19/295,582

(22) Filed: Aug. 9, 2025

Related U.S. Application Data
(63) Continuation of application No. 18/444,211, filed on Feb. 16, 2024.
(60) Provisional application No. 63/583,009, filed on Sep. 15, 2023.

(51) Int. Cl. H10D 30/43; H10D 30/01; H10D 30/67; H10D 62/10; H10D 64/01

(52) U.S. Cl. CPC H10D 30/43; H10D 30/014; H10D 30/6735; H10D 62/121; H10D 64/017

(57) ABSTRACT

The present disclosure describes a semiconductor device having a dielectric fin structure. The semiconductor device includes a channel structure on a substrate and a dielectric fin structure on the substrate and adjacent to the channel structure. The channel structure extends along a first direction. The dielectric fin structure includes a stiff dielectric material and extends along a second direction parallel to the first direction. The semiconductor device further includes an isolation structure extending through the channel structure. The isolation structure is in contact with the dielectric fin structure.

### CROSS-REFERENCE TO RELATED APPLICATION

This application is a continuation application of U.S. Non-Provisional patent application Ser. No. 18/444,211, filed on Feb. 16, 2024, titled “Dielectric Fin Structures for Semiconductor Devices,” which claims the benefit of U.S. Provisional Patent Application No. 63/583,009, titled “Approaches to Eliminate the Lay-Out-Dependent Effect in Cut Layer by Implementing Dummy Fins,” filed on Sep. 15, 2023, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates a top-down view of a semiconductor device having a dielectric fin structure, in accordance with some embodiments.

FIG. 2 illustrates an isometric view of a semiconductor device having a dielectric fin structure, in accordance with some embodiments.

FIGS. 3-5 illustrate cross-sectional views of a semiconductor device having a dielectric fin structure, in accordance with some embodiments.

FIG. 6 is a flow diagram of a method for fabricating a semiconductor device having a dielectric fin structure, in accordance with some embodiments.

FIGS. 7-68 illustrate top-down, isometric, and cross-sectional views of a semiconductor device having a dielectric fin structure at various stages of its fabrication, in accordance with some embodiments.

FIG. 69 is a flow diagram of another method for fabricating a semiconductor device having a dielectric fin structure, in accordance with some embodiments.

FIGS. 70-85 illustrate cross-sectional views of a semiconductor device having a dielectric fin structure at various stages of its fabrication using another method, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, continuous polysilicon on diffusion edge (CPODE) or continuous metal on diffusion edge (CMODE) processes can be used to pattern nanostructure transistors with trench isolation structures. The trench isolation structures can reduce leakage current through source/drain (S/D) epitaxial structures, transistor channels, and substrates. The nanostructure transistors can include finFETs, gate-all-around field effect transistors (GAA FETs), nanosheet transistors, nanowire transistors, multi-bridge channel transistors, nano-ribbon transistors, and other similar structured transistors. However, the CPODE and CMODE processes can create tensile and/or compressive forces on surfaces of a substrate, produce deformation of the substrate, and cause a lay-out dependent effect (LDE) of the nanostructure transistors on the substrate. The iso-dense depth loading effect of the LDE can increase leakage current of the nanostructure transistors. The iso-dense critical dimension loading effect of the LDE can cause damage to S/D epitaxial structures. The gate deformation from the LDE can cause a threshold voltage (Vₜ) shift of the nanostructure transistors.

Various embodiments of the present disclosure provide methods for forming a dielectric fin structure in a semiconductor device (e.g., a nanostructure transistor) and/or other semiconductor devices in an integrated circuit (IC). In some embodiments, a channel structure extending along a first direction can be formed on a substrate. A dielectric fin structure can be formed on the substrate and adjacent to the channel structure. In some embodiments, the dielectric fin structure can include a stiff dielectric material and extend along a second direction parallel to the first direction. In some embodiments, the stiff dielectric material can have a Young's modulus greater than silicon oxide. In some embodiments, the stiff dielectric material can have a Young's modulus greater than about 75 GPa. A gate structure can be formed on the channel structure and the dielectric fin structure. An isolation structure can be formed on the gate structure and can extend through the gate structure and the channel structure. In some embodiments, the isolation structure can be in contact with the dielectric fin structure. In some embodiments, the isolation structure can be formed by CPODE or CMODE processes. In some embodiments, the dielectric fin structure can reduce the deformation of the substrate and minimize the LDE effect of the semiconductor devices on the substrate. Accordingly, the dielectric fin structure can reduce device leakage current, minimize damage to S/D epitaxial structures, and reduce Vₜ shift of the semiconductor devices on the substrate.

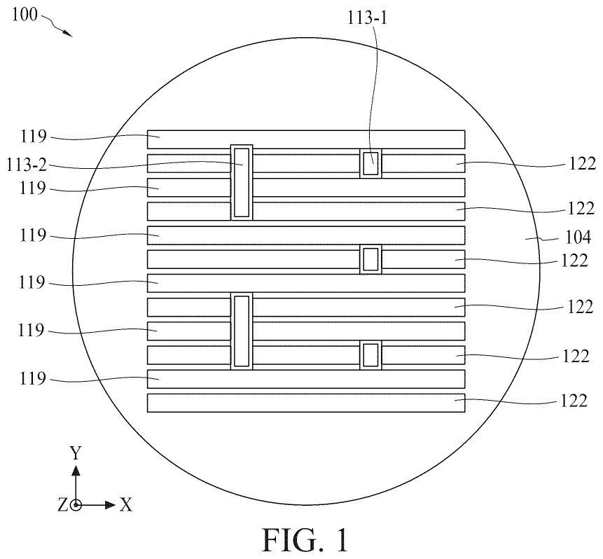

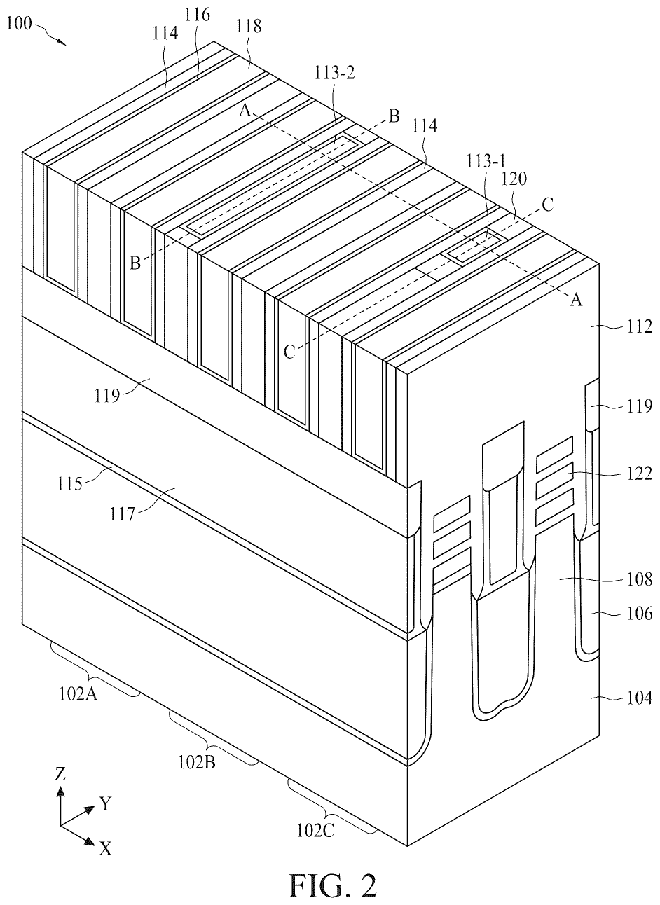

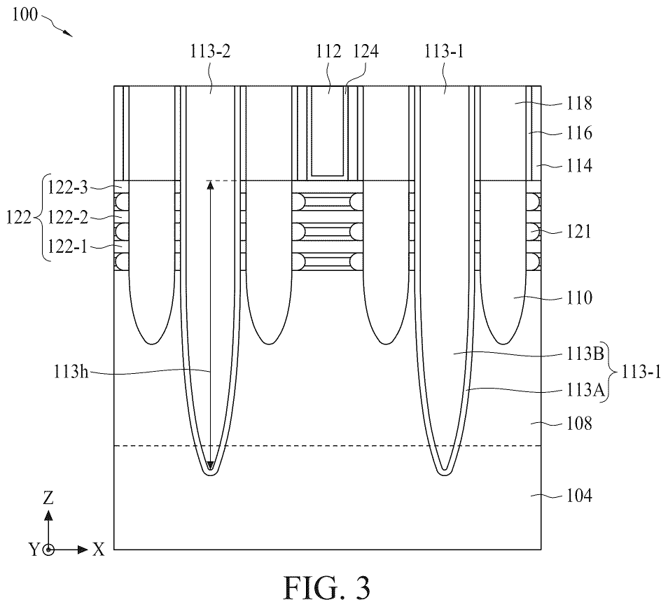

FIG. 1 illustrates a top-down view of a semiconductor device 100 having a dielectric fin structure, in accordance with some embodiments. FIG. 2 illustrates a partial isometric view of semiconductor device 100 having a dielectric fin structure, in accordance with some embodiments. FIGS. 3-5 illustrate partial cross-sectional views of semiconductor device 100 having a dielectric fin structure across lines A-A, B-B, and C-C shown in FIG. 2, respectively, in accordance with some embodiments.

In some embodiments, semiconductor device 100 can include transistors 102A-102C, as shown in FIG. 2. In some embodiments, transistors 102A-102C can include nanostructure transistors. The nanostructure transistors can include finFETs, GAA FETs, nanosheet transistors, nanowire transistors, multi-bridge channel transistors, nano-ribbon transistors, and other similar structured transistors. The nanostructure transistors can provide a channel in a stacked nanosheet/nanowire configuration. In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 2 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-5, semiconductor device 100 having transistors 102A-102C can be formed on a substrate 104 and can be isolated by shallow trench isolation (STI) regions 106. Each of transistors 102A-102C can include fin structures 108, nanostructures 122-1, 122-2, and 122-3 (collectively referred to as “nanostructures 122”), gate dielectric layer 124, gate structures 112, gate spacers 114, inner spacers 121, and S/D structures 110. In some embodiments, semiconductor device can further include trench isolation structures 113-1 and 113-2 (collectively referred to as “trench isolation structures 113”), a protection layer 115, an etch stop layer (ESL) 116, an isolation layer 117, an interlayer dielectric (ILD) layer 118, a dielectric fin structures 119, and gate isolation structures 120.

Referring to FIGS. 1-5, substrate 104 can include a semiconductor material, such as silicon. In some embodiments, substrate 104 includes a crystalline silicon substrate (e.g., silicon wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

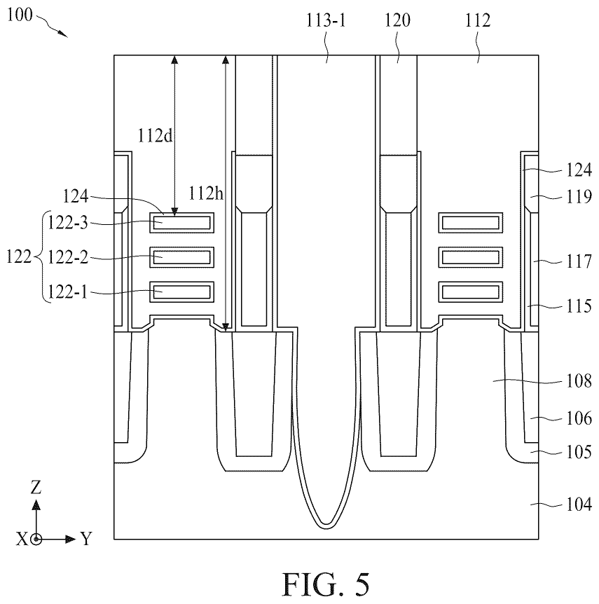

STI regions 106 can provide electrical isolation between transistors 102A-102C and from neighboring transistors (not shown) on substrate 104 and/or neighboring active and passive elements (not shown) integrated with or deposited on substrate 104. In some embodiments, as shown in FIG. 5, an oxide liner 105 can be disposed between STI regions 106 and substrate 104 for protection of fin structures 108 and nanostructures 122 during the formation of STI regions 106. In some embodiments, oxide liner 105 can include silicon oxide or other suitable dielectric materials. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-5, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-5, nanostructures 122 and fin structures 108 can extend along an X-axis. In some embodiments, nanostructures 122 and fin structures 108 can be disposed on substrate 104. Nanostructures 122 can include a stack of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2-5, nanostructures 122 under gate structures 112 can form channel regions of semiconductor device 100 and represent current carrying channel structures of semiconductor device 100. In some embodiments, nanostructures 122 can have a thickness along a Z-axis ranging from about 5 nm to about 8 nm. In some embodiments, nanostructures 122 can have a width along a Y-axis ranging from about 15 nm to about 50 nm. In some embodiments, nanostructures 122 can have a width along an X-axis ranging from about 15 nm to about 25 nm. In some embodiments, a spacing between adjacent nanostructures 122 along a Z-axis can range from about 8 nm to about 12 nm. Though three layers of nanostructures 122 are shown in FIGS. 2-5, transistors 102A-102C can have any number of nanostructures 122.

Referring to FIGS. 2-5, gate dielectric layer 124 can be disposed on nanostructures 122, fin structures 108, STI regions 106, isolation layer 117, and dielectric fin structures 119. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 2-5, gate structures 112 can be disposed on gate dielectric layer 124. In some embodiments, gate structures 112 can include one or more work function metal layers and a metal fill. The one or more work function metal layers can include work function metals to tune the Vₜ of transistors 102A-102C. In some embodiments, gate structures 112 for NFET and PFET devices can have substantially the same work-function metal. In some embodiments, gate structures 112 for NFET and PFET devices can have different work-function metals. In some embodiments, as shown in FIGS. 2-5, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ). In some embodiments, as shown in FIG. 5, gate structures 112 can have a height 112h along a Z-axis from top surfaces of STI regions 106. Height 112h can range from about 80 nm to about 120 nm. In some embodiments, as shown in FIG. 5, a distance 112d along a Z-axis between top surfaces of gate structures 112 and top surfaces of top nanostructures 122-3 can range from about 30 nm to about 40 nm.

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 2 and 3, gate spacers 114 can be disposed on sidewalls of gate structures 112 and in contact with gate dielectric layer 124, according to some embodiments. Inner spacers 121 can be disposed adjacent to end portions of nanostructures 122 and between S/D structures 110 and gate structures 112. Gate spacers 114 and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 and inner spacers 121 can include the same insulating material. In some embodiments, gate spacers 114 and inner spacers 121 can include different insulating materials. In some embodiments, gate spacers 114 and inner spacers 121 can include a single layer or a stack of insulating layers. In some embodiments, gate spacers 114 and inner spacers 121 can have a low-k dielectric material with a dielectric constant less than about 3.9 (e.g., about 3.5, about 3.0, or about 2.8).

S/D structures 110 can be disposed on fin structures 108 and on opposing sides of gate structures 112. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. For p-type in-situ doping, p-type doping precursors, such as diborane (B₂H₆), boron trifluoride (BF₃), and other p-type doping precursors, can be used.

In some embodiments, S/D structures 110 can include one or more epitaxial layers, where each epitaxial layer can have different compositions. In some embodiments, each of the one or more epitaxial layers can include Si and differ from each other based on, for example, doping concentration and/or epitaxial growth process conditions. In some embodiments, each of the one or more epitaxial layers can include silicon germanium and differ from each other based on, for example, doping concentration, epitaxial growth process conditions, and/or relative concentration of germanium with respect to silicon.

Referring to FIGS. 1-5, trench isolation structures 113 can be disposed on substrate 104 and on the edge between different diffusion regions (e.g., n and p regions). In some embodiments, trench isolation structures 113 can include a liner 113A and a dielectric fill 113B. In some embodiments, liner 113A can include silicon nitride, silicon carbonitride, or other suitable dielectric materials. Dielectric fill 113B can include silicon oxide, silicon oxynitride, silicon oxycarbonitride, or other suitable dielectric materials. In some embodiments, liner 113A can protect nanostructures 122, fin structures 108, and substrate 104 (e.g., preventing oxidation) during the formation of dielectric fill 113B. In some embodiments, trench isolation structures 113 can extend through gate structures 112, nanostructures 122, STI regions 106, and fin structures 108 into substrate 104. In some embodiments, trench isolation structures 113 can be formed by the CPODE and/or CMODE processes to reduce leakage current flowing through S/D structures 110, nanostructures 122, and substrate 104. In some embodiments, as shown in FIGS. 1-5, trench isolation structures 113 can include short trench isolation structures extending over about 1 to about 3 fin structures 108. In some embodiments, trench isolation structures 113 can include long trench isolation structures extending over more than about 3 fin structures 108. In some embodiments, as shown in FIG. 3, trench isolation structures 113 can have a height 113h along a Z-axis from a bottom surface of trench isolation structures 113 to top surfaces of top nanostructures 122-3. Height 113h can range from about 120 nm to about 250 nm. If height 113h is less than about 120 nm, trench isolation structures 113 may not extend through STI regions 106 and may not reduce the leakage current. If height 113h is greater than about 250 nm, the well structure of transistors 102A-102C may be damaged and the device performance may be degraded. Additionally, the leakage current may not be further reduced but manufacturing cost may increase.

In some embodiments, as shown in FIGS. 2-5, protection layer 115 can be disposed on STI regions 106 and between gate dielectric layer 124 and isolation layer 117. In some embodiments, protection layer 115 can include silicon carbonitride or other suitable materials to protect adjacent structures during formation of isolation layer 117. In some embodiments, isolation layer 117 can be disposed on protection layer 115 and can include silicon oxide or other suitable materials.

Referring to FIGS. 1-5, dielectric fin structures 119 can be disposed on isolation layer 117 and between adjacent nanostructures 122. In some embodiments, as shown in FIG. 1, dielectric fin structures 119 and nanostructures 122 can be disposed on substrate 104 in an alternate configuration. In some embodiments, dielectric fin structures 119 can include a stiff dielectric material. In some embodiments, the stiff dielectric material can have a Young's modulus greater than silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon, silicon nitride, silicon carbide, silicon carbonitride, silicon oxycarbonitride, aluminum oxide, or other suitable lower k dielectric materials. In some embodiments, dielectric fin structures 119 can have one or more layers of different stiff dielectric material. In some embodiments, dielectric fin structures 119 can have a higher etch resistivity to remain after various etching processes. In some embodiments, the bottom surface of dielectric fin structures 119 can be above the top surfaces of top nanostructures 122-3. If the bottom surface of dielectric fin structures 119 is below the top surface of top nanostructures 122-3, parasitic capacitance between adjacent nanostructure transistors may increase. In some embodiments, dielectric fin structures 119 can reduce the deformation of substrate 104 and minimize the LDE effect of semiconductor device 100 on substrate 104. Accordingly, as shown in FIG. 3, gate structures 112 can be substantially vertical with respect to the X-axis and Y-axis (e.g., top surfaces of nanostructures 122). In some embodiments, gate structures 112 adjacent to trench isolation structures 113 may bend less than about 2 degrees. In some embodiments, with dielectric fin structures 119, a width difference along an X-axis of nanostructures 122 between isolated regions and dense regions can be less than about 1.5 nm and a height difference of trench isolation structures 113 can be less than about 15 nm. As a result, dielectric fin structures 119 can reduce leakage current caused by the iso-dense depth loading effect, minimize damage to S/D epitaxial structures caused by the iso-dense critical dimension loading effect, and reduce Vₜ shift of semiconductor device 100 caused by gate deformation.

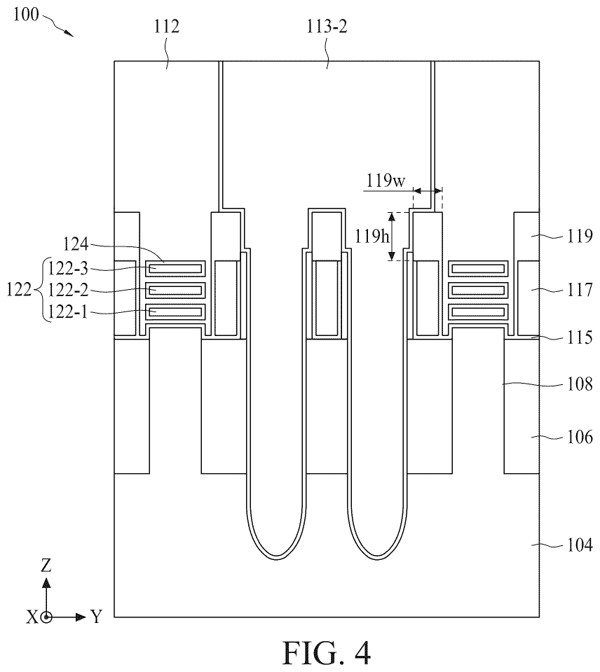

In some embodiments, as shown in FIG. 4, dielectric fin structures 119 can have a width 119w along a Y-axis ranging from about 15 nm to about 20 nm. In some embodiments, as shown in FIG. 4, dielectric fin structures 119 can have a height 119h along a Z-axis ranging from about 20 nm to about 30 nm. In some embodiments, a first ratio of height 119h to distance 120d can range from about 0.6 to about 0.8. A second ratio of height 119h to height 120h can range from about 0.15 to about 0.3. If height 119h is less than about 20 nm, the first ratio is less than about 0.6, or the second ratio is less than about 0.15, dielectric fin structures 119 may not remain after the CPODE or CMODE processes. If height 119h is greater than about 30 nm, the first ratio is greater than about 0.8, or the second ratio is greater than about 0.3, parasitic capacitance between adjacent nanostructure transistors may increase. In some embodiments, width 119w, height 119h, and the first and second ratios can depend on the stiff dielectric material of dielectric fin structures 119. In some embodiments, a bottom surface of dielectric fin structures 119 and a top surface of top nanostructures 122-3 can be substantially at the same level. In some embodiments, as shown in FIG. 4, dielectric fin structures 119 can be surrounded by trench isolation structures 113.

Referring to FIGS. 2-5, ESL 116 can be disposed on S/D structures 110, dielectric fin structures 119, and sidewalls of gate spacers 114. ESL 116 can be configured to protect S/D structures 110, dielectric fin structures 119, and gate structures 112 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and dielectric fin structures 119. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 2 and 5, gate isolation structures 120 can be disposed on trench isolation structures 113. In some embodiments, gate isolation structures 120, dielectric fin structures 119, isolation layer 117, and trench isolation structures 113 can electrically isolate gate structures 112 into two portions. In some embodiments, gate isolation structures 120 can include silicon nitride, silicon oxide, and/or other suitable dielectric materials. In some embodiments, gate isolation structures 120 can include a single dielectric layer or a stack of dielectric layers. In some embodiments, gate isolation structures 120, dielectric fin structures 119, and isolation layer 117 can extend vertically through gate structures 112.

In some embodiments, semiconductor device 100 can further include S/D contact structures, gate contact structures, metal lines, metal vias, interconnects, and additional ILD layers, which are not described in detail for clarity.

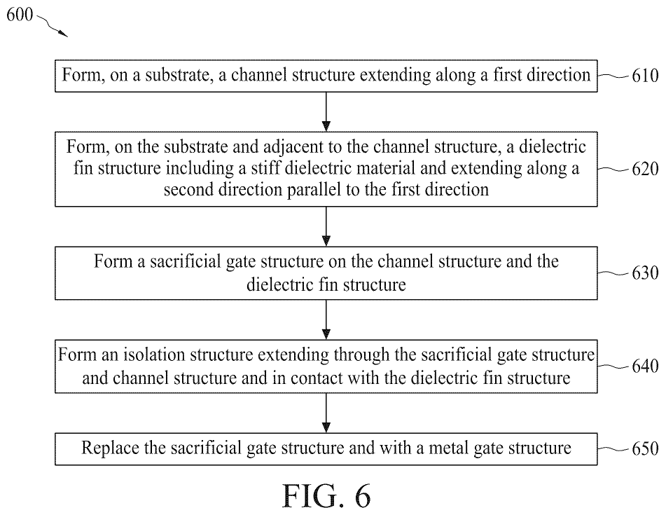

FIG. 6 is a flow diagram of a method 600 for fabricating semiconductor device 100 having a dielectric fin structure, in accordance with some embodiments. Method 600 may not be limited to nanostructure transistor devices and can be applicable to other devices that would benefit from the dielectric fin structure. Additional fabrication operations may be performed between various operations of method 600 and may be omitted merely for clarity and ease of description. Additional processes can be provided before, during, and/or after method 600; one or more of these additional processes are briefly described herein. Moreover, not all operations may be needed to perform the disclosure provided herein. Additionally, some of the operations may be performed simultaneously or in a different order than shown in FIG. 6. In some embodiments, one or more other operations may be performed in addition to or in place of the presently-described operations.

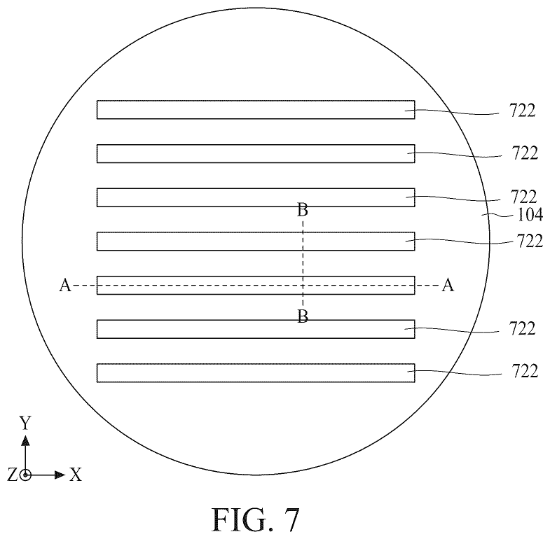

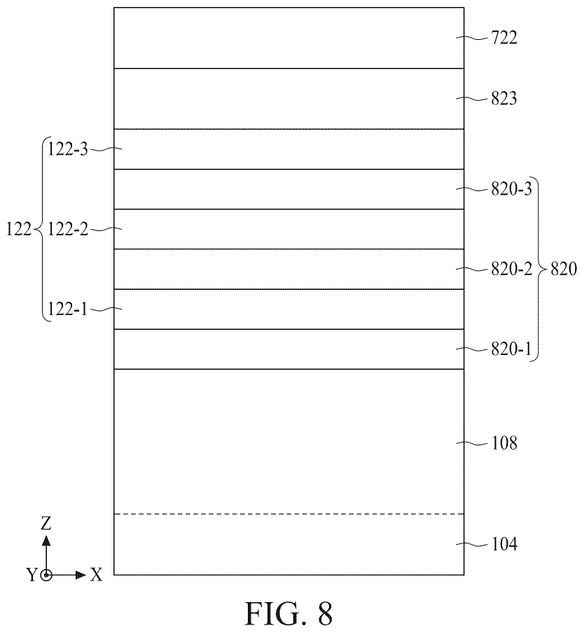

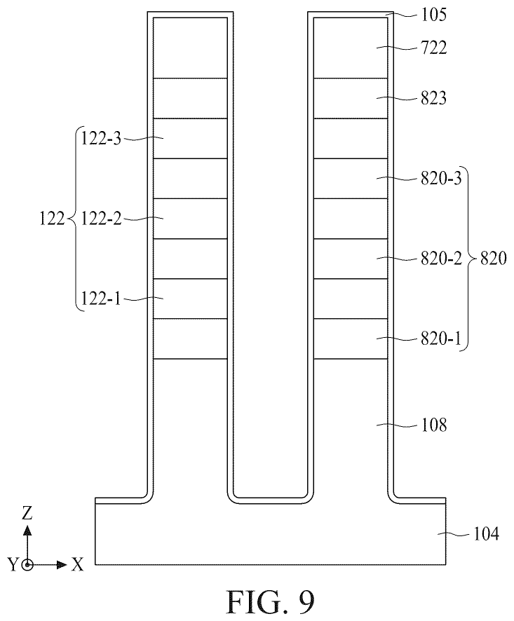

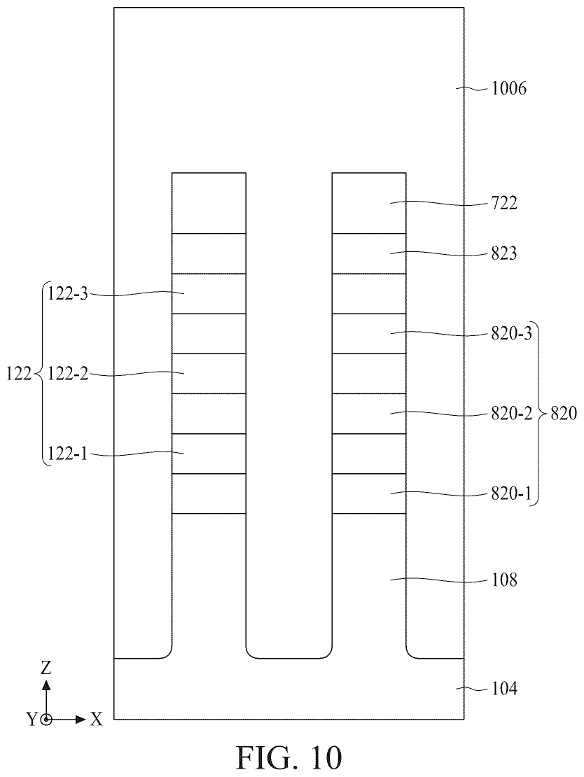

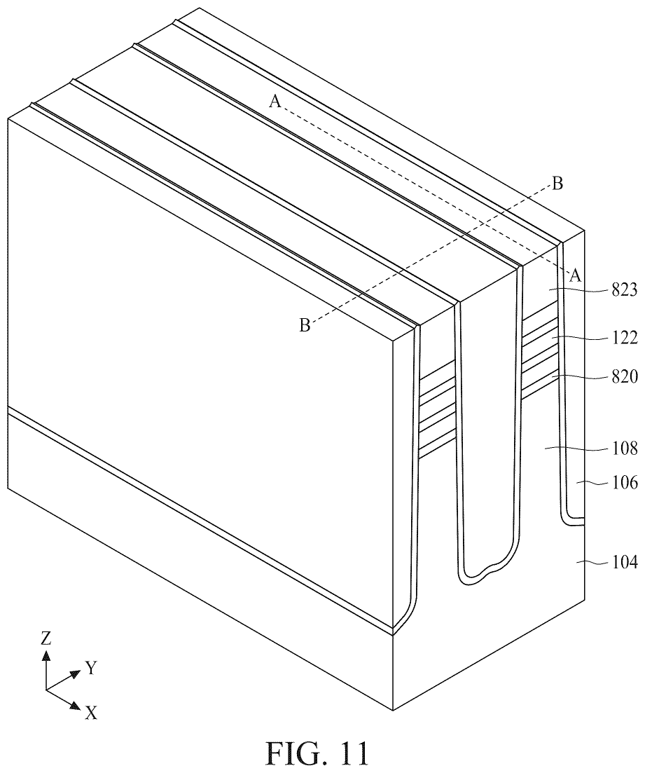

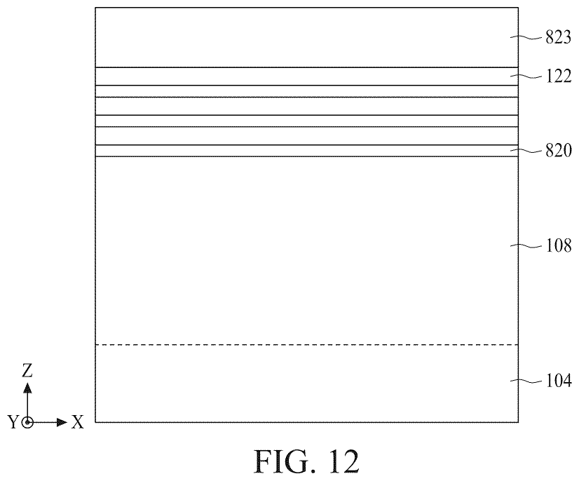

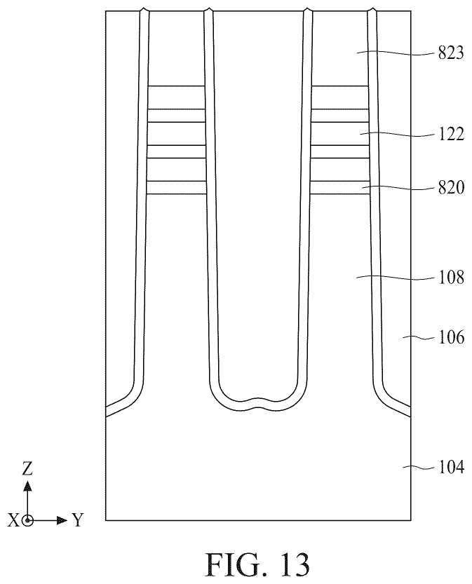

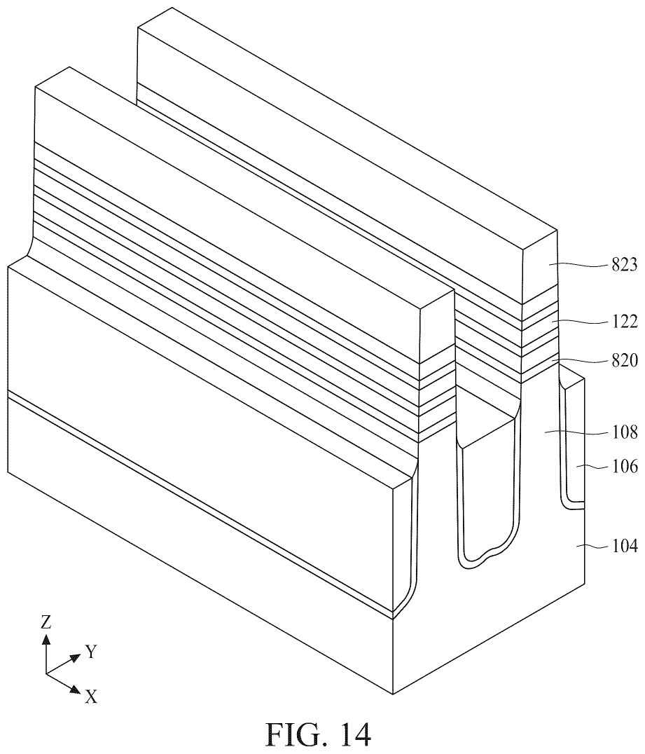

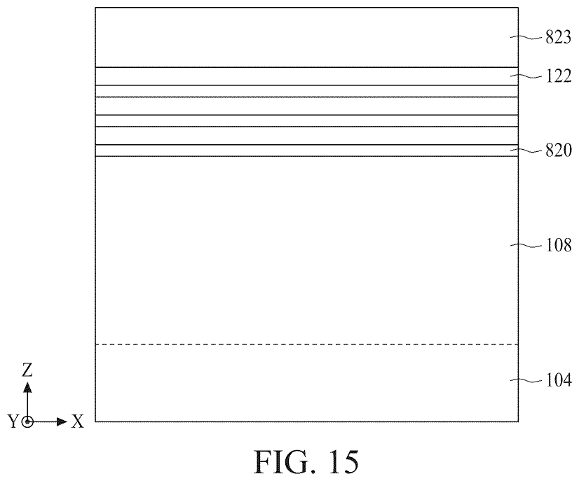

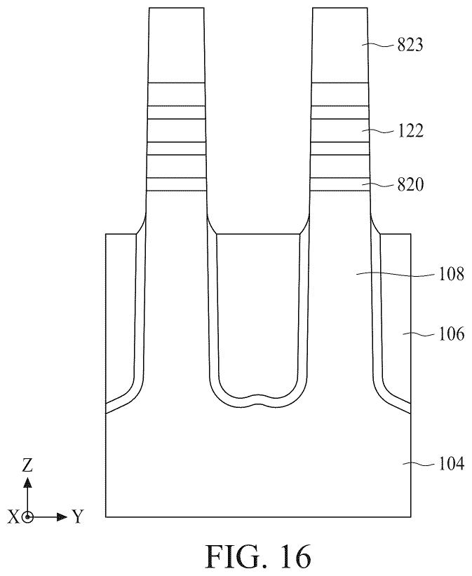

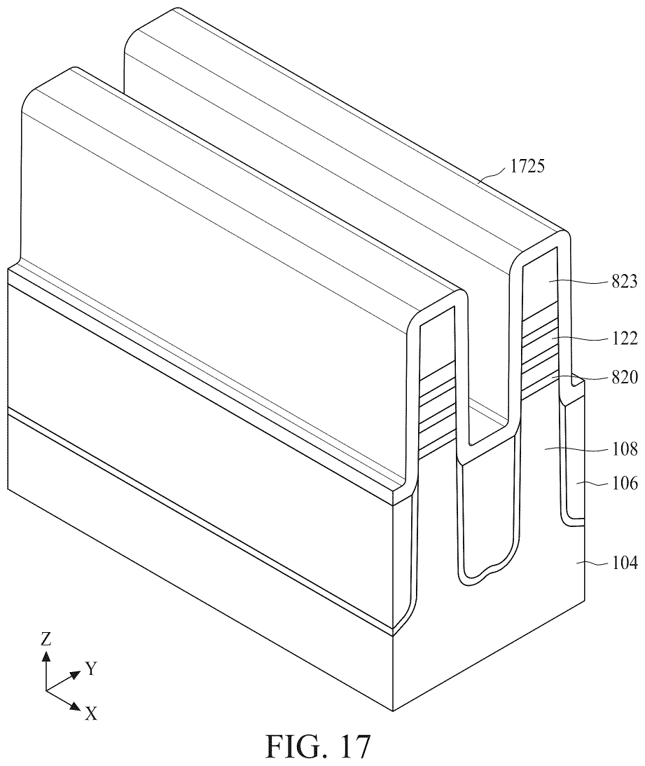

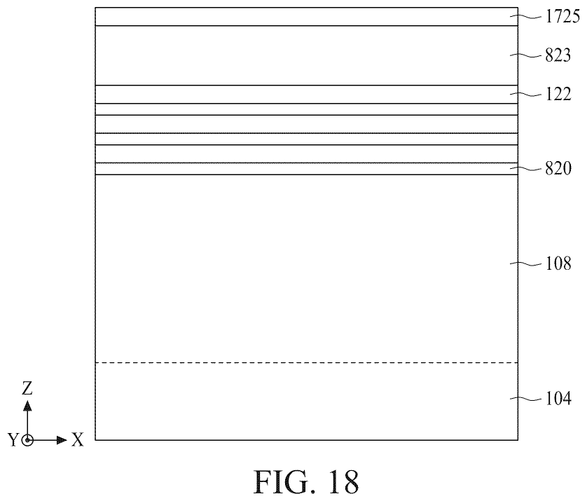

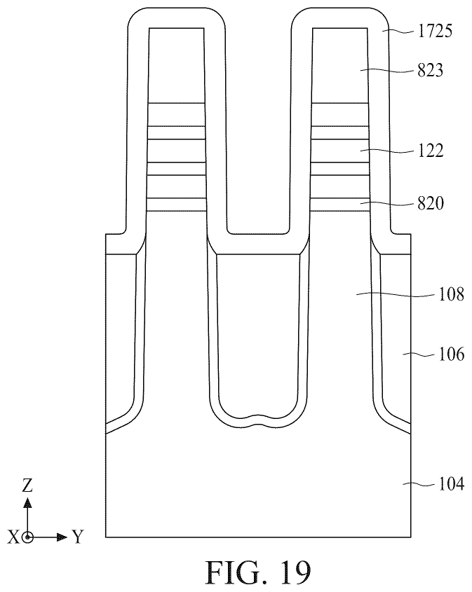

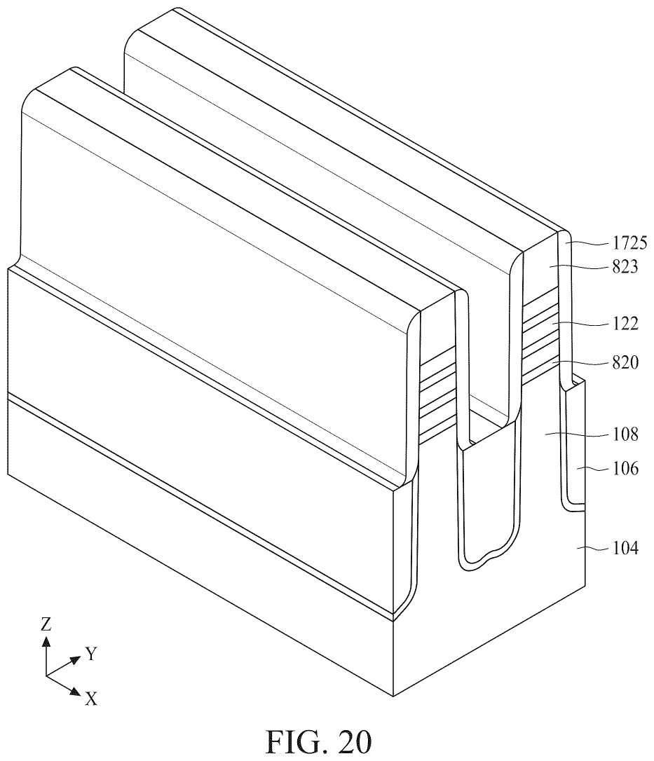

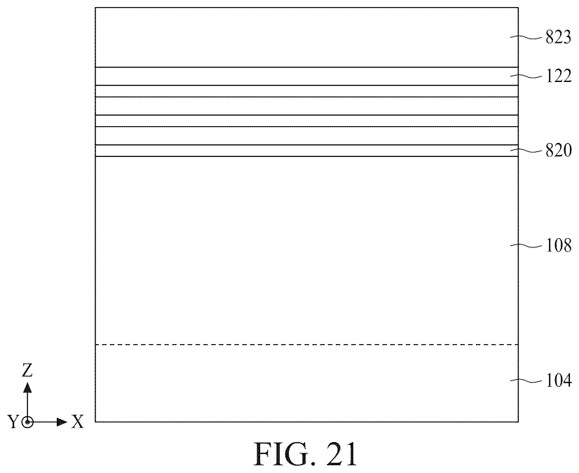

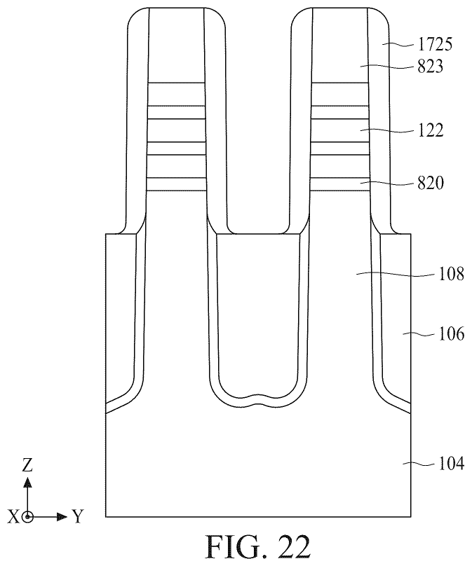

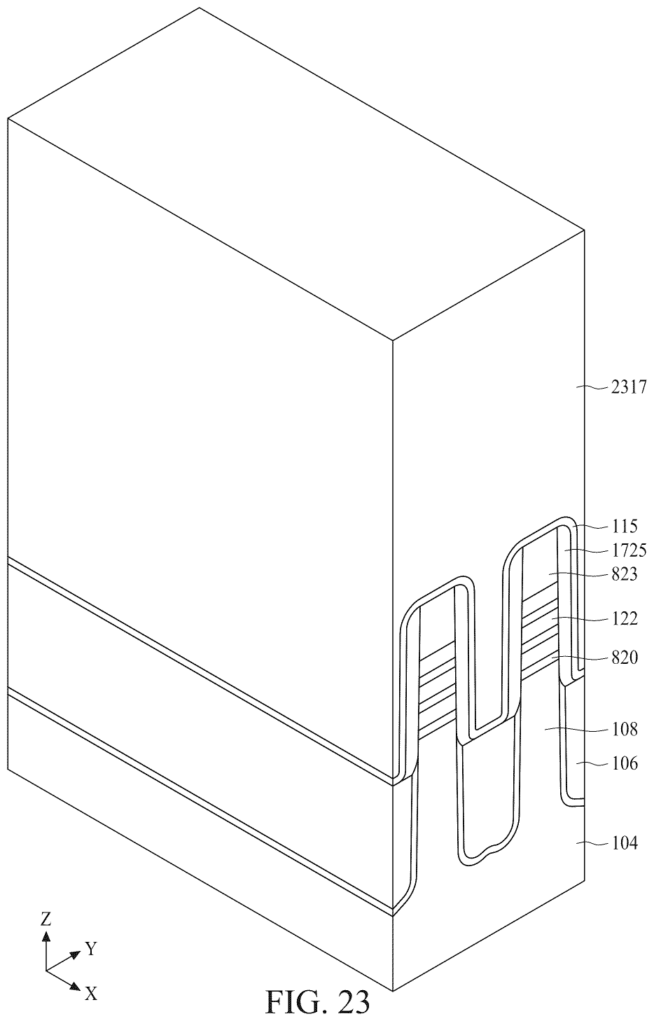

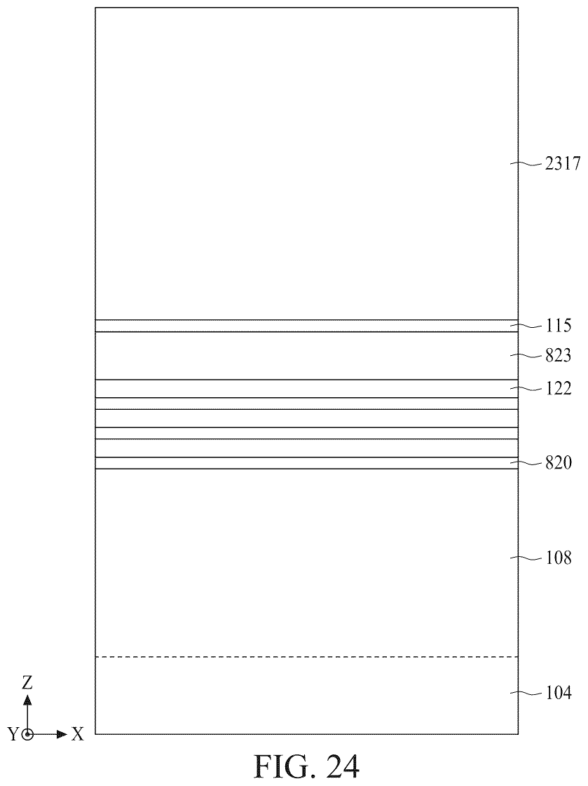

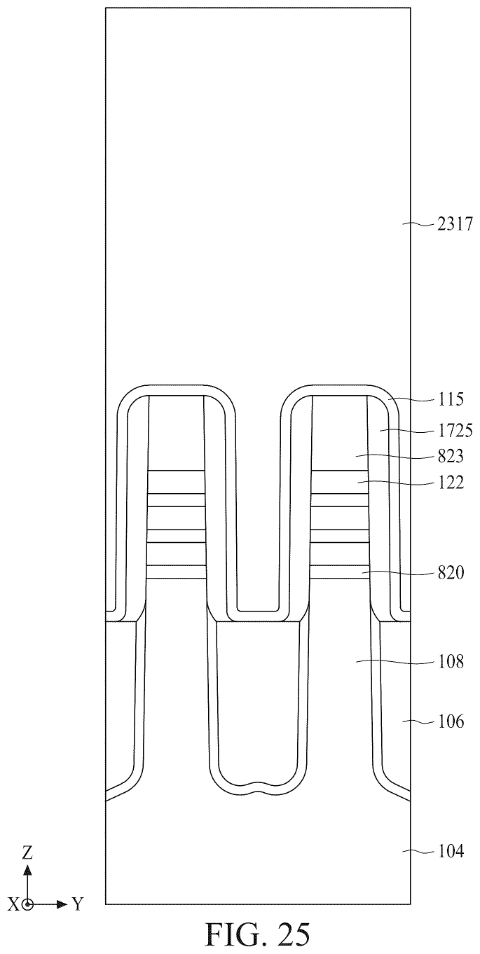

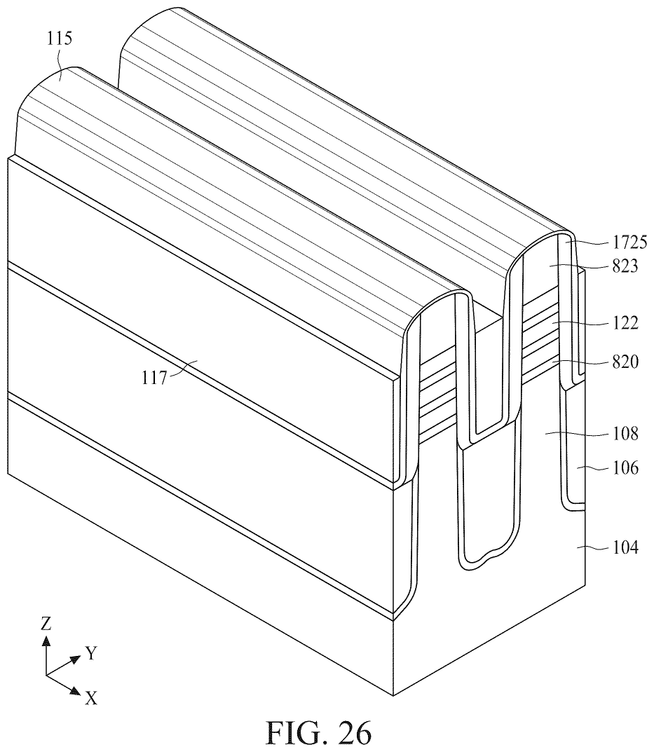

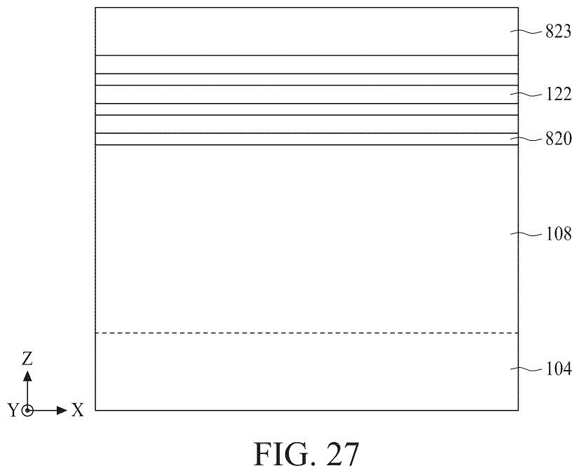

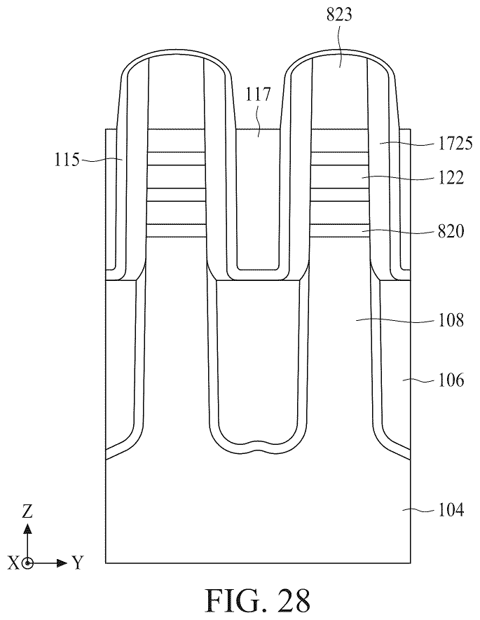

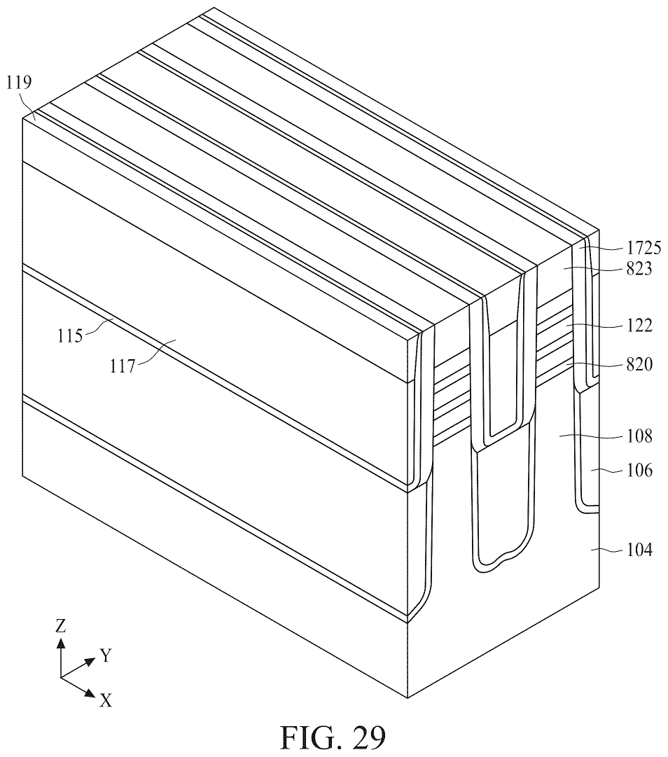

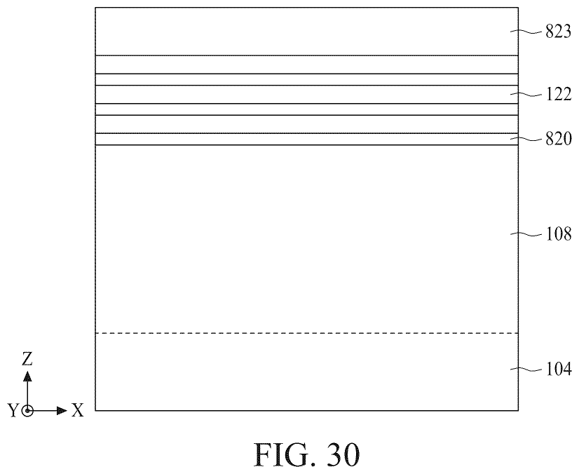

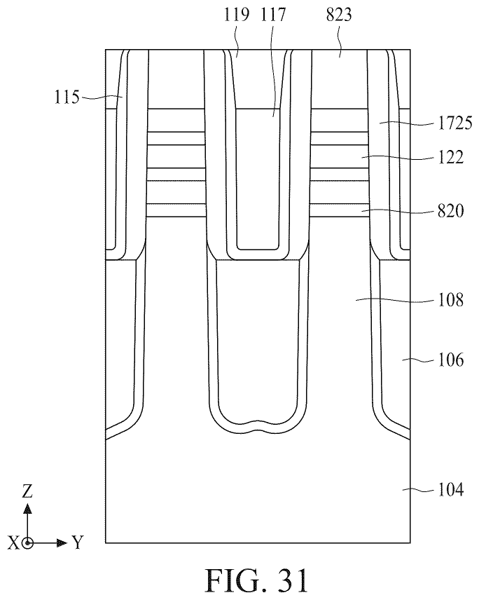

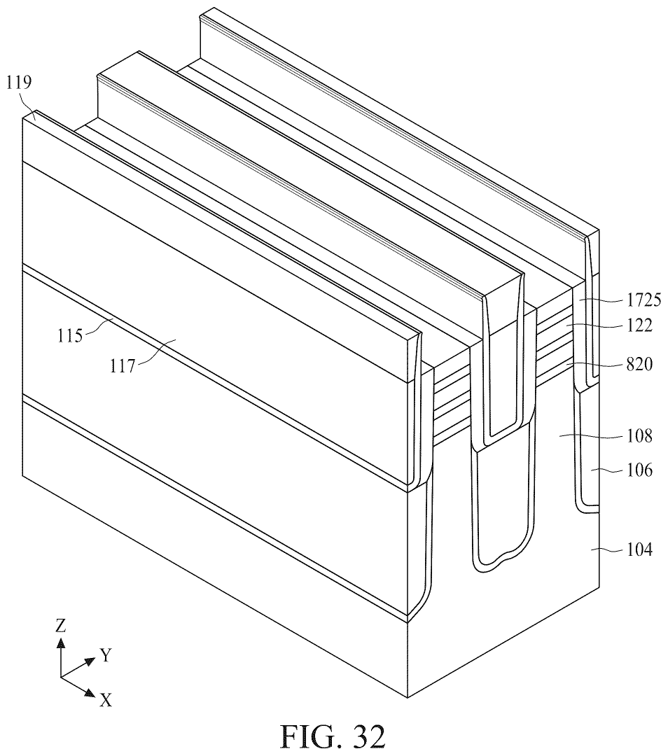

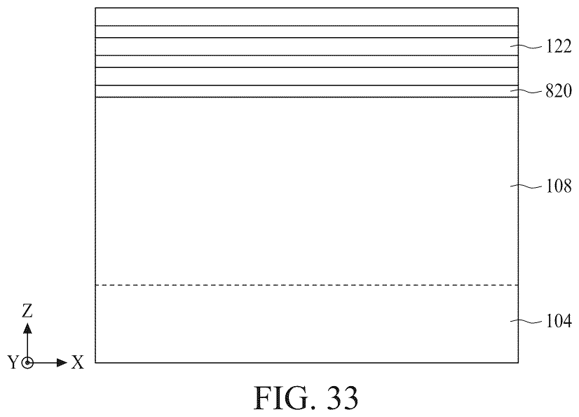

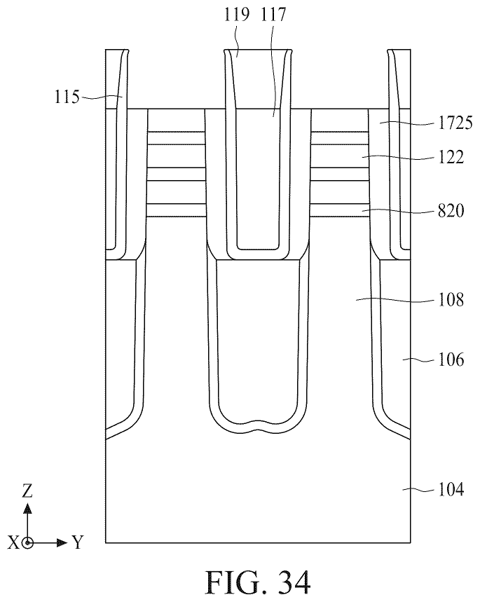

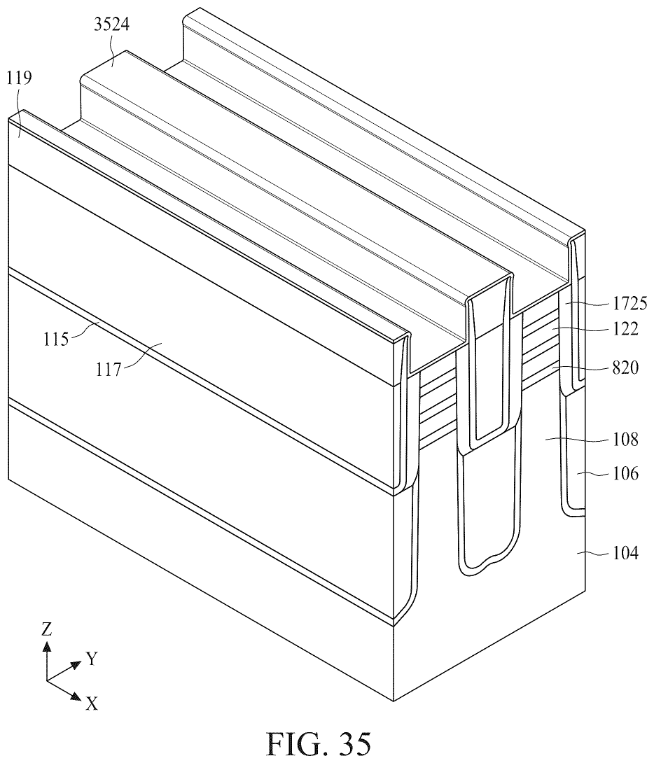

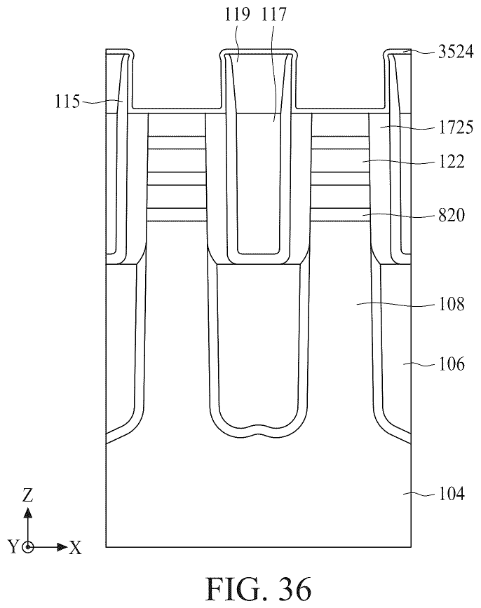

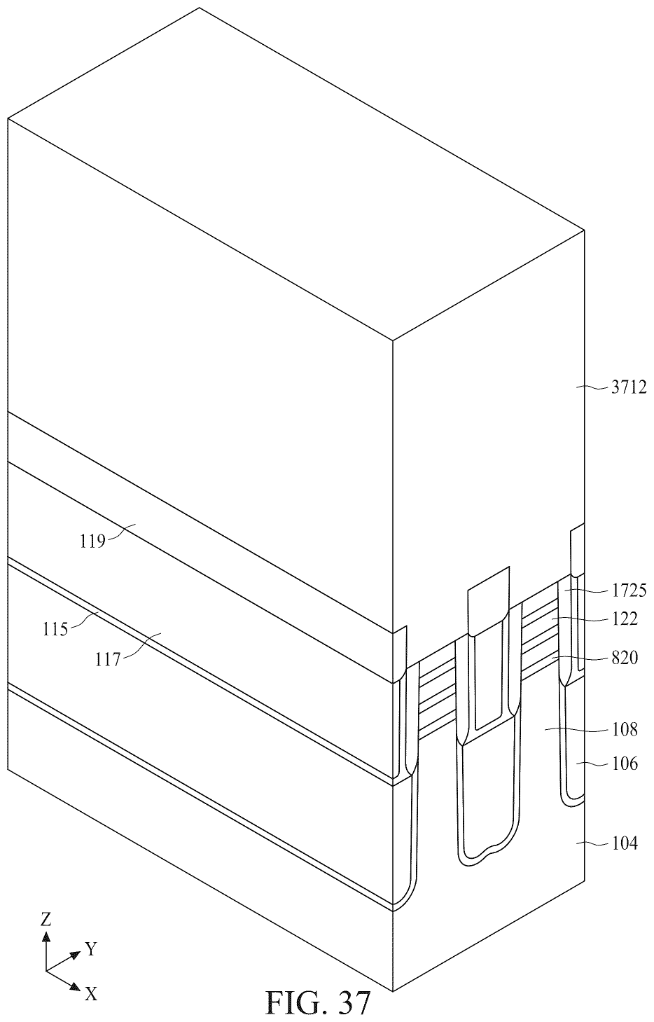

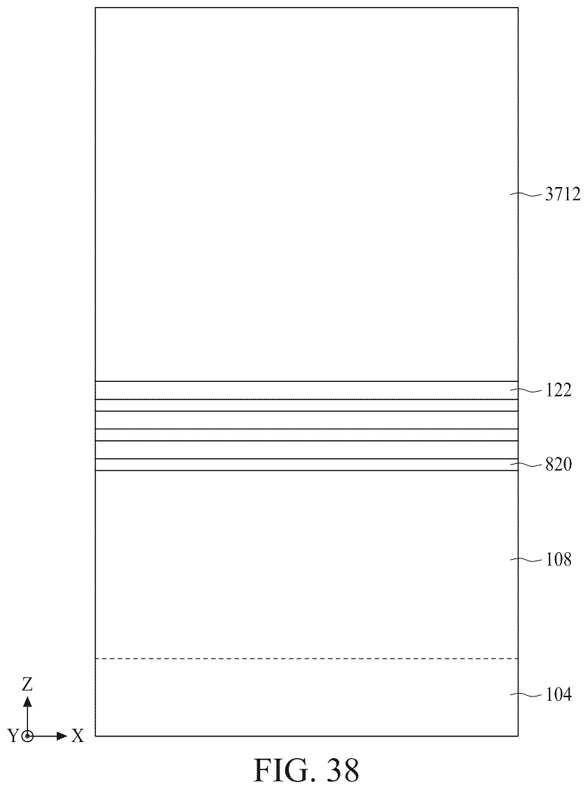

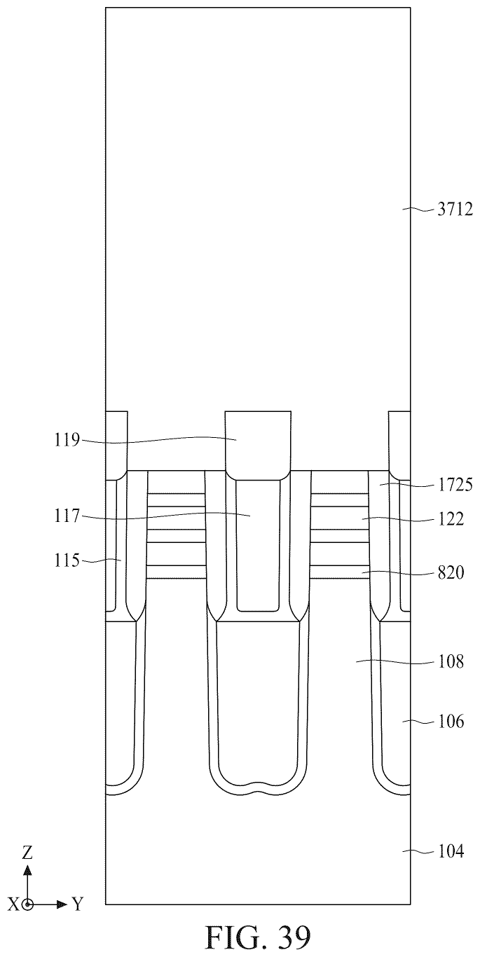

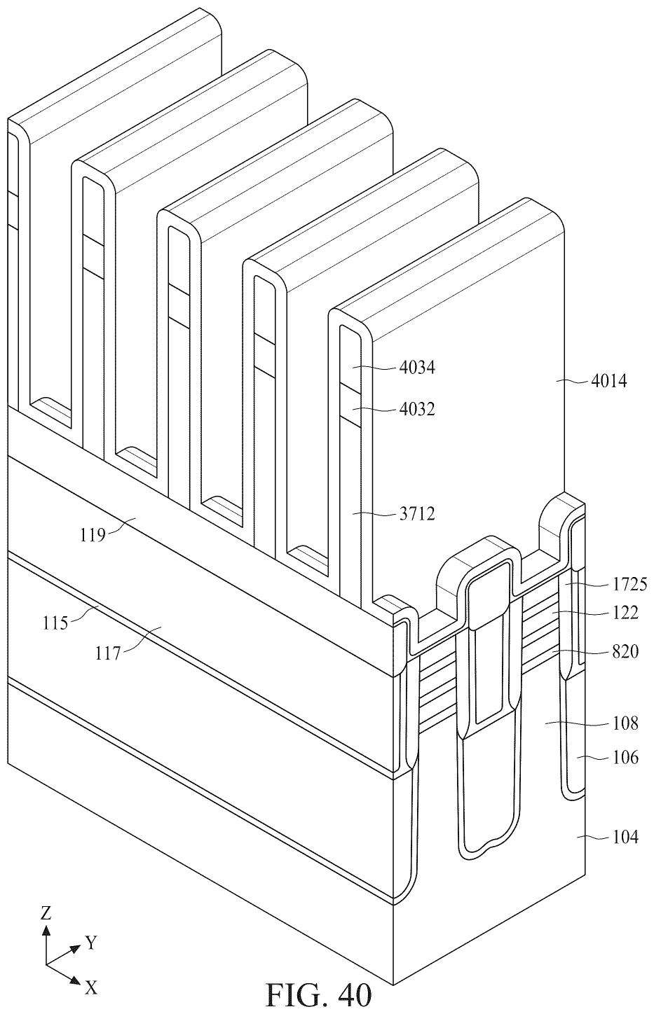

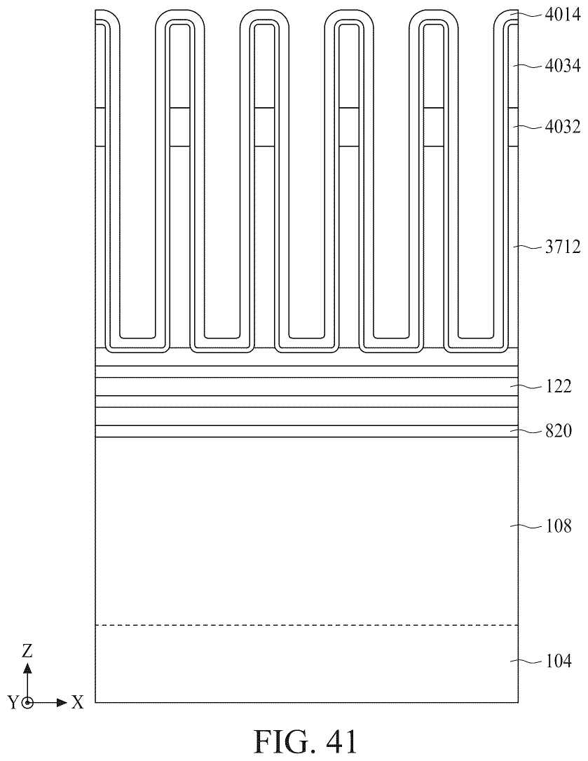

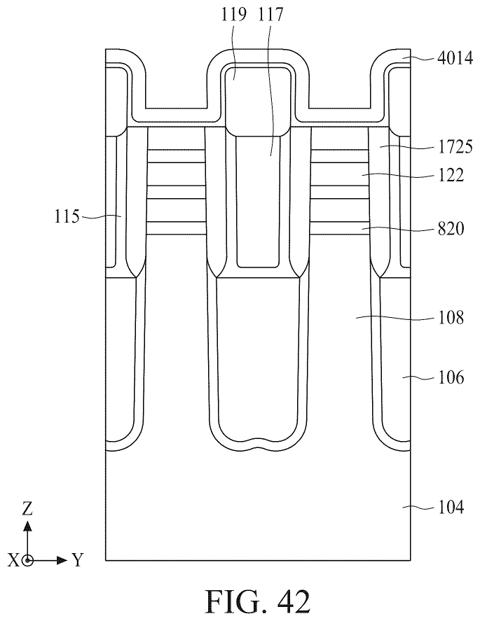

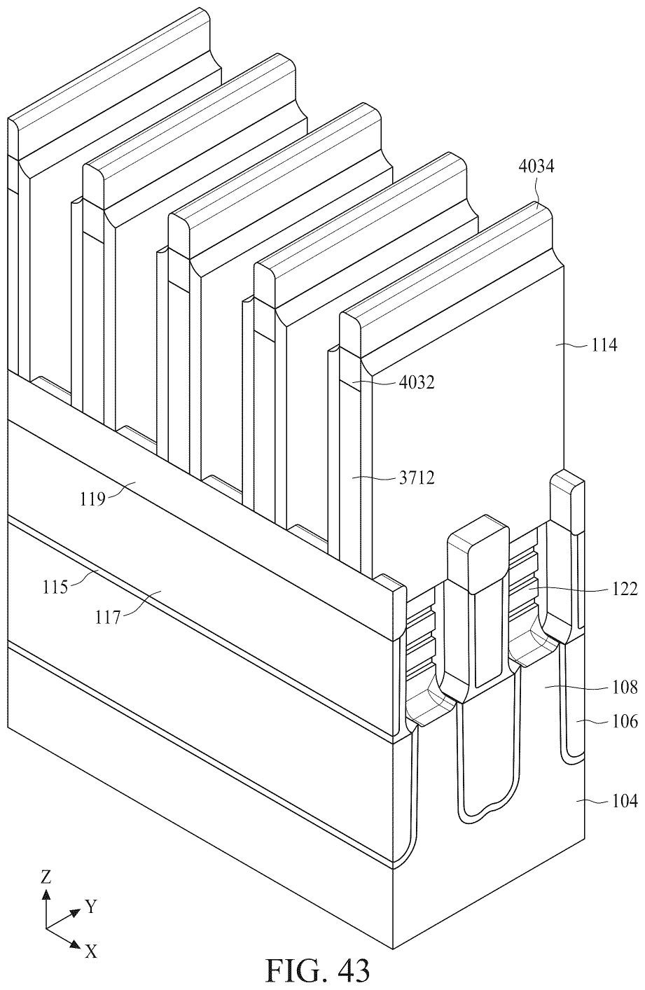

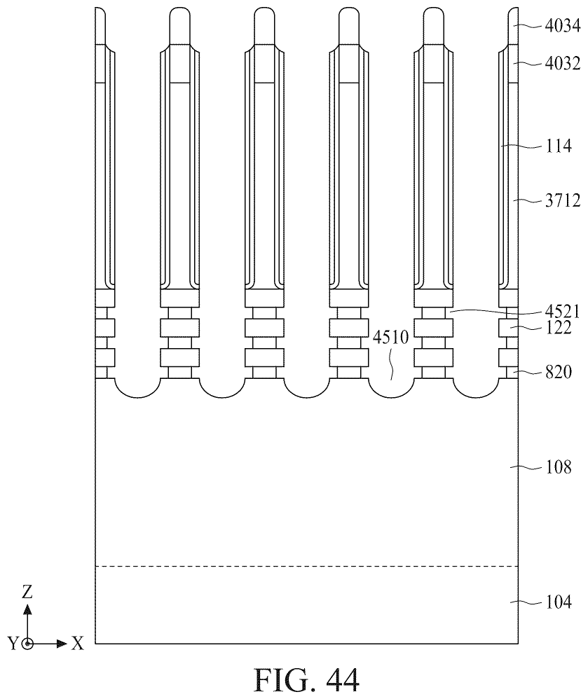

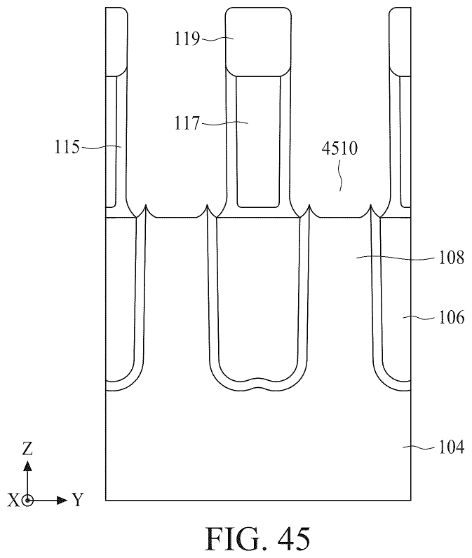

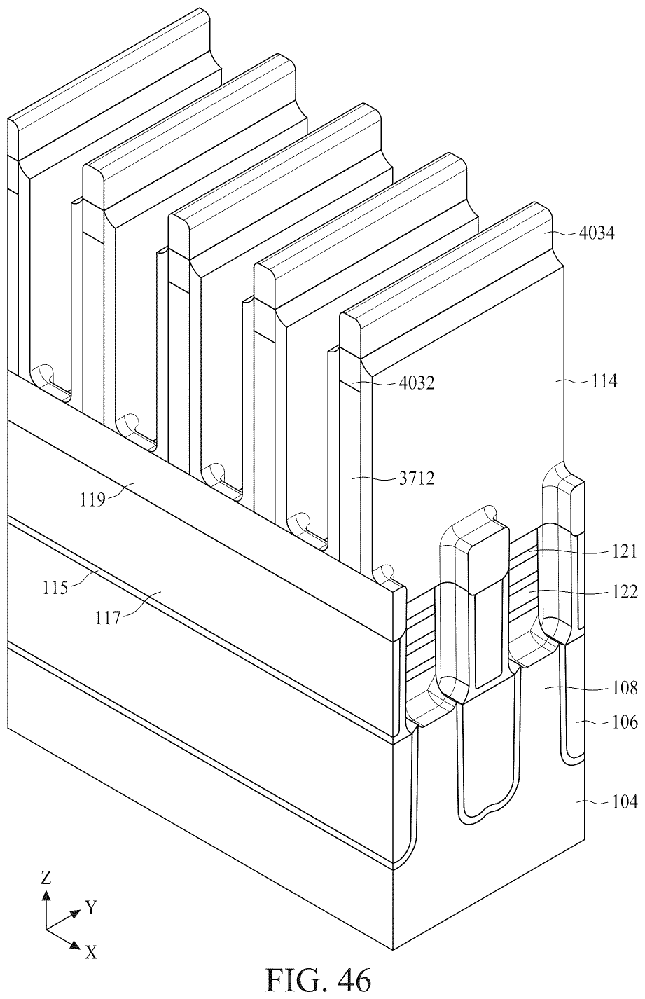

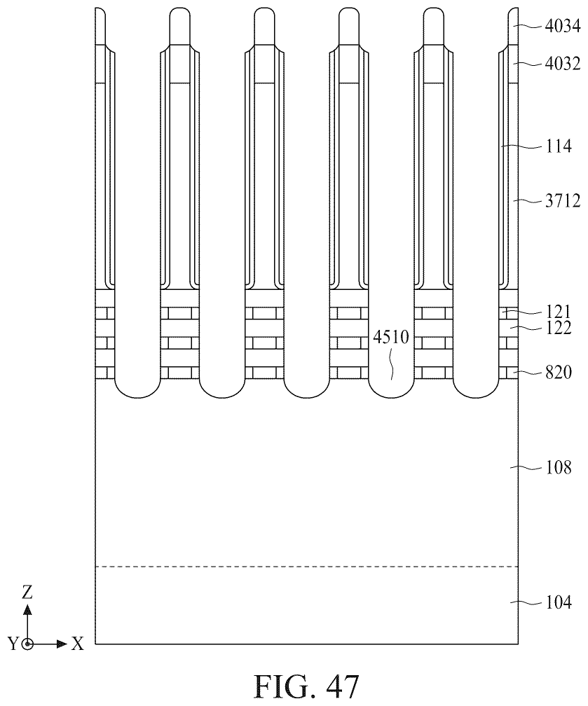

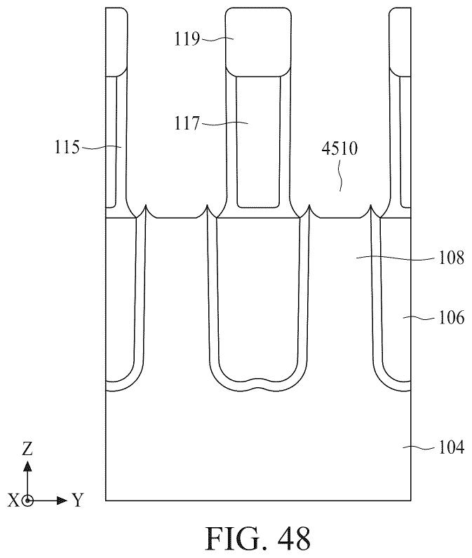

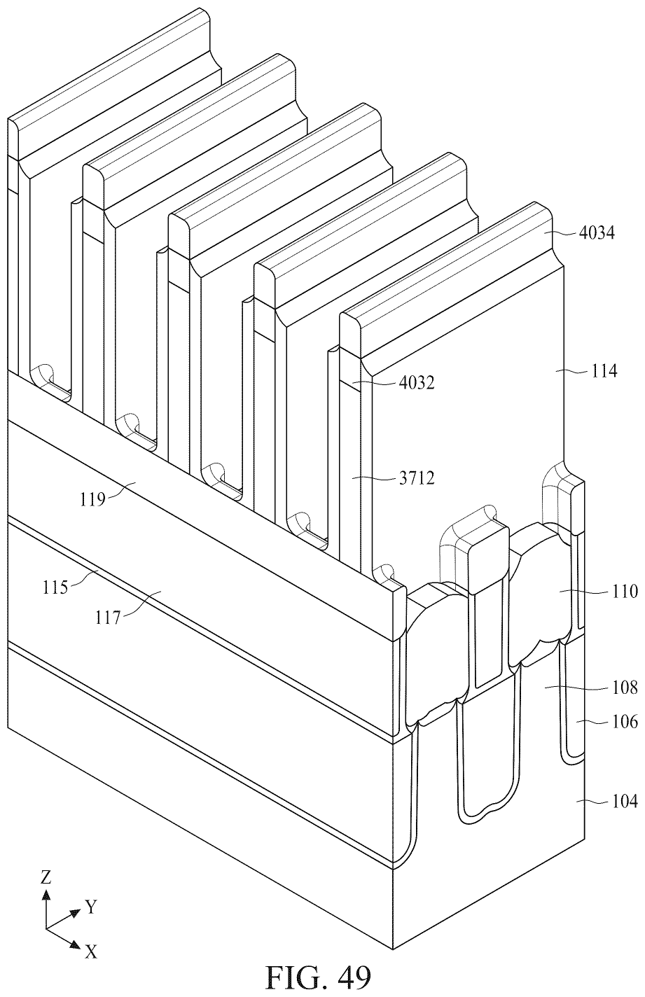

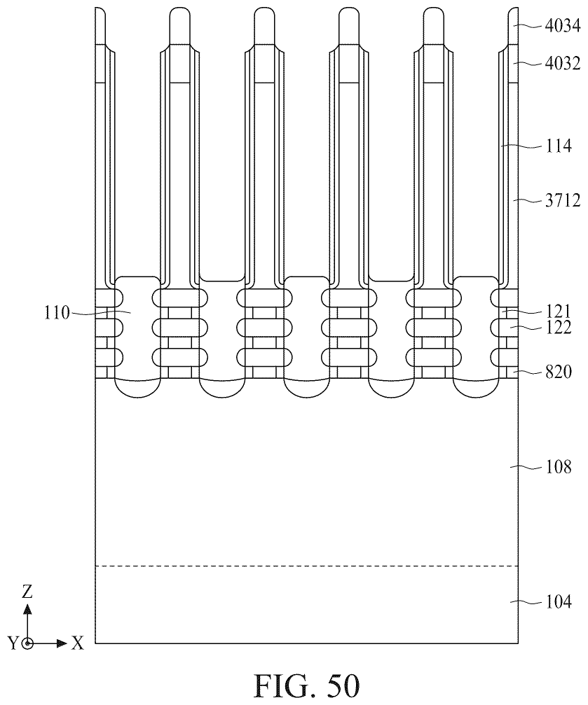

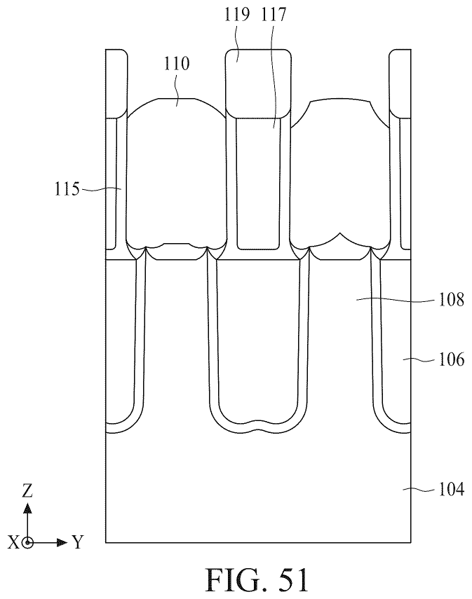

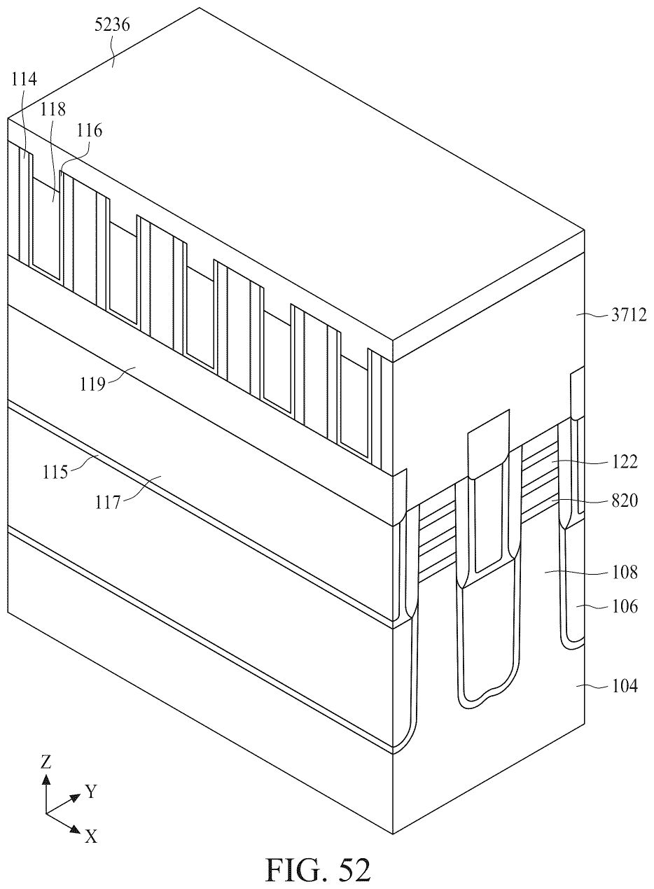

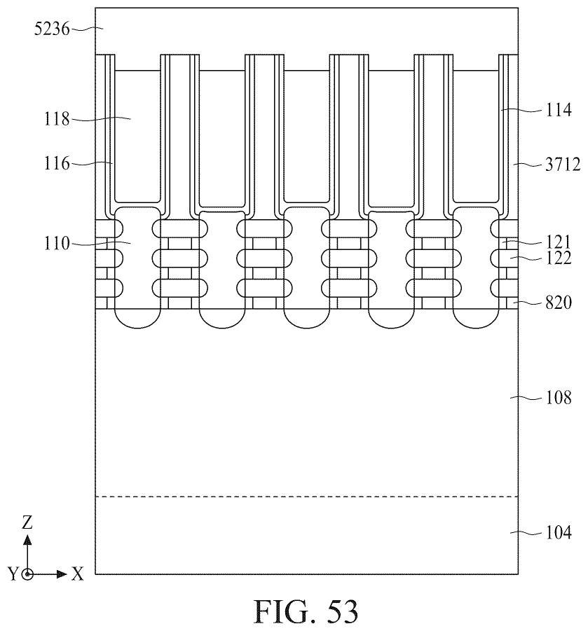

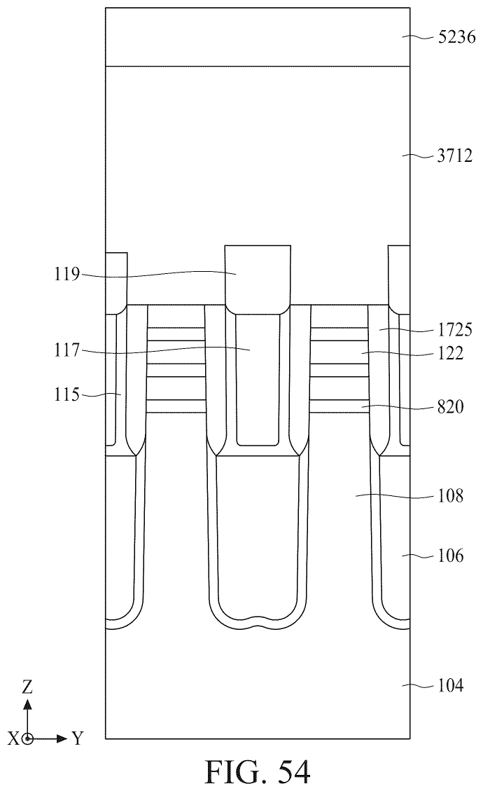

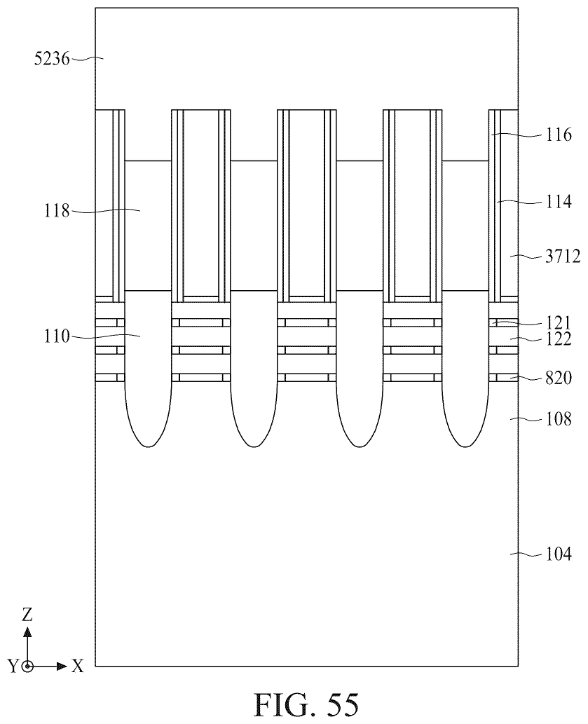

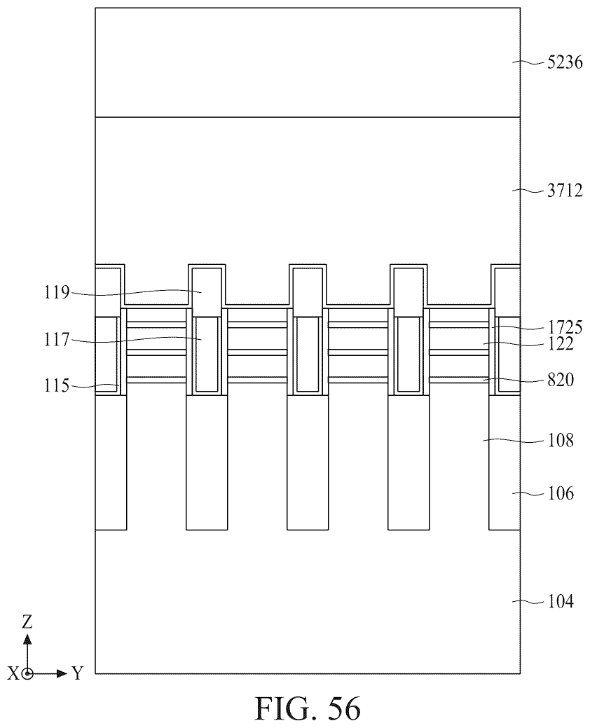

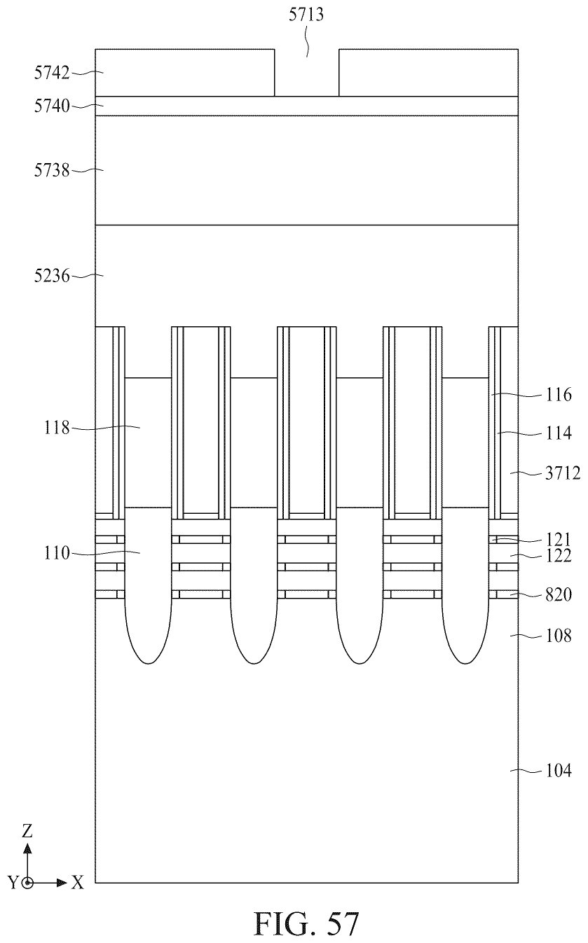

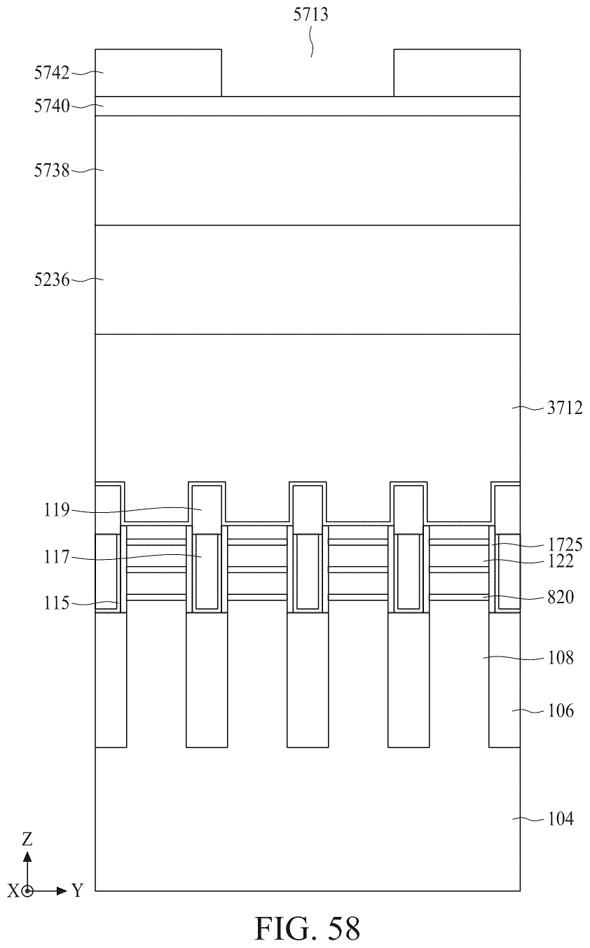

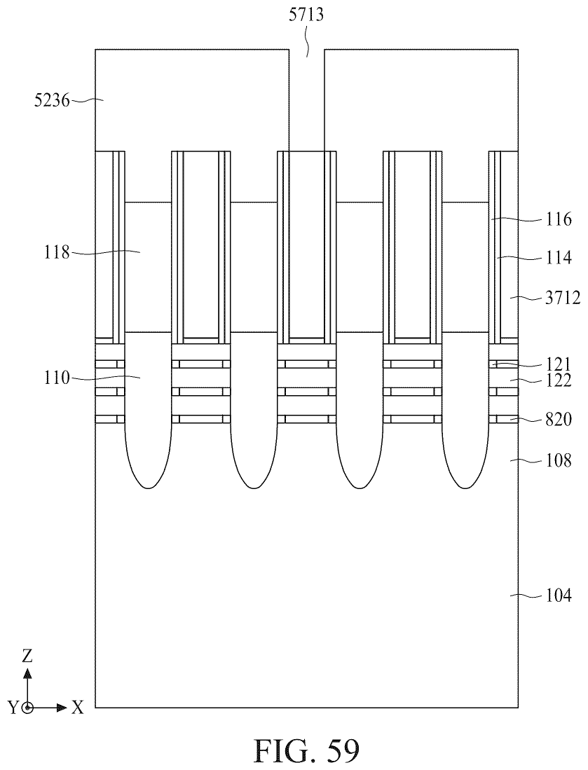

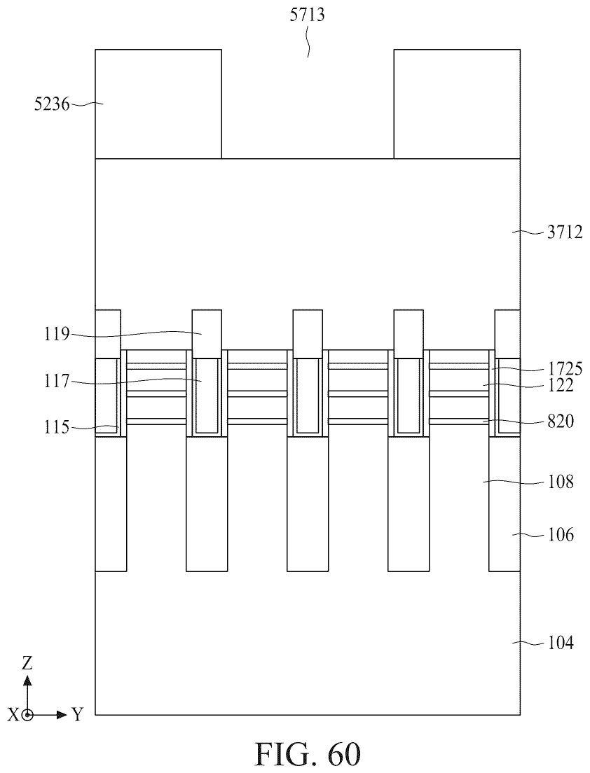

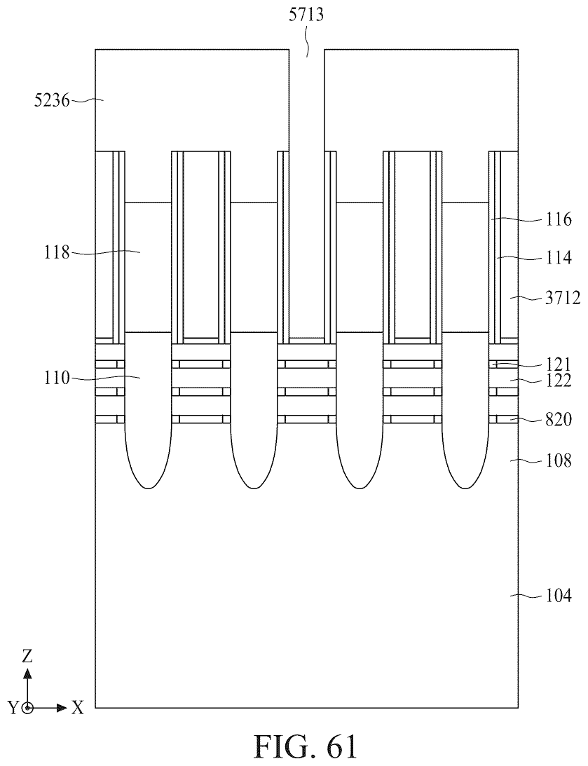

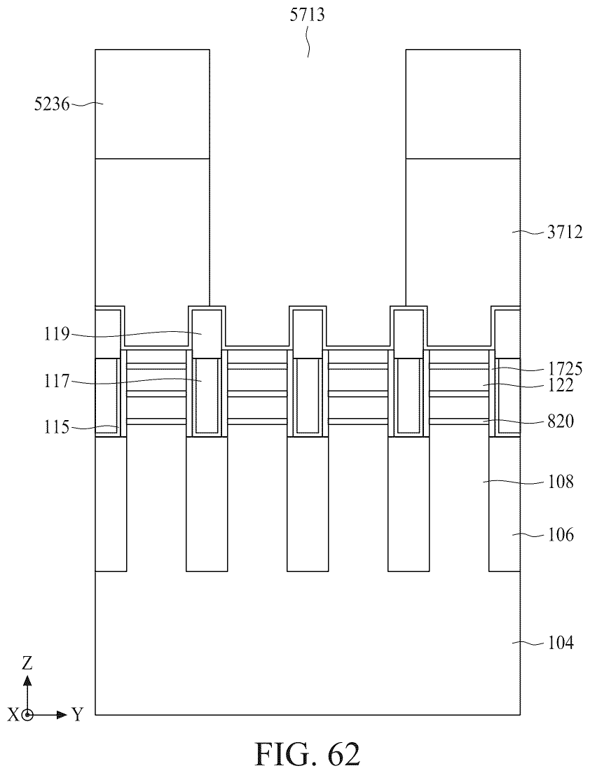

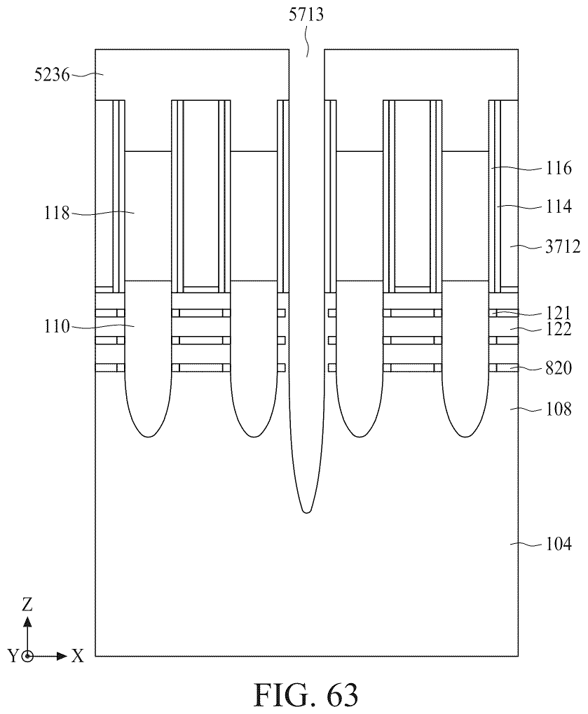

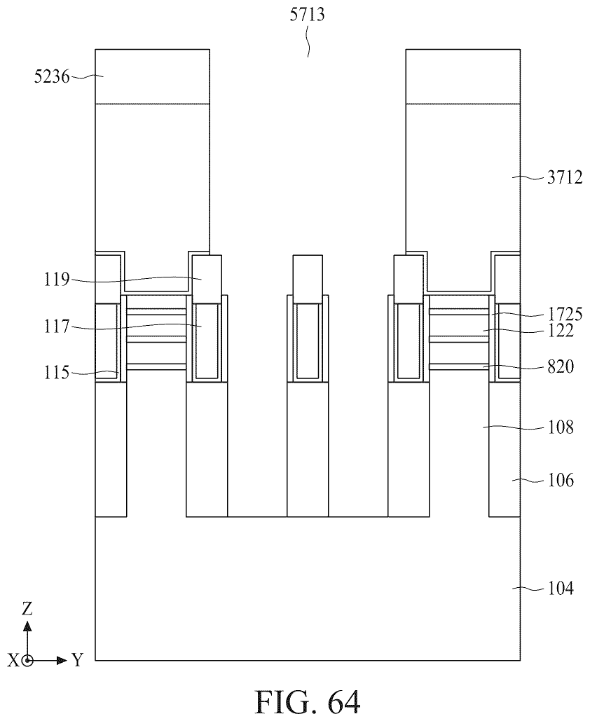

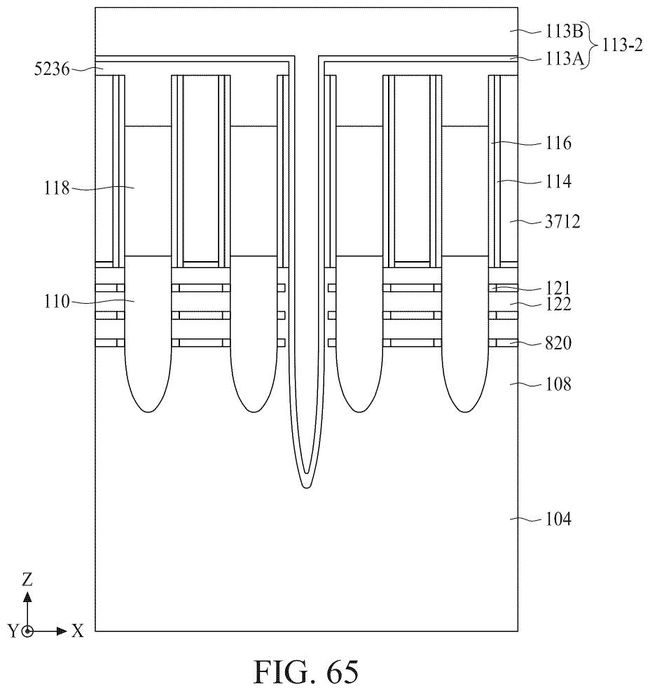

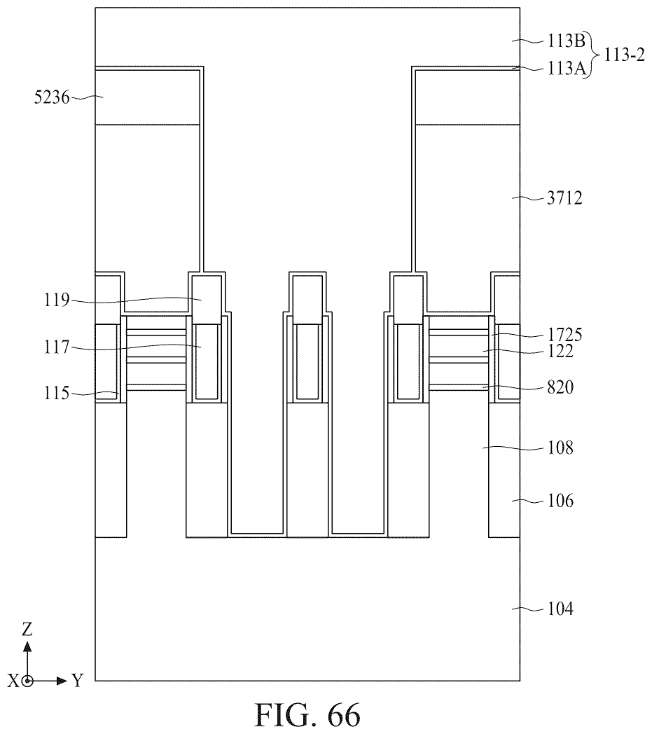

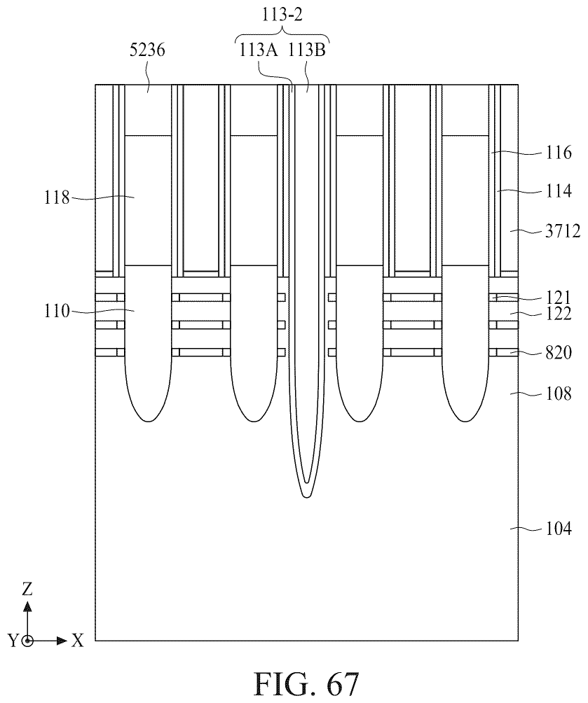

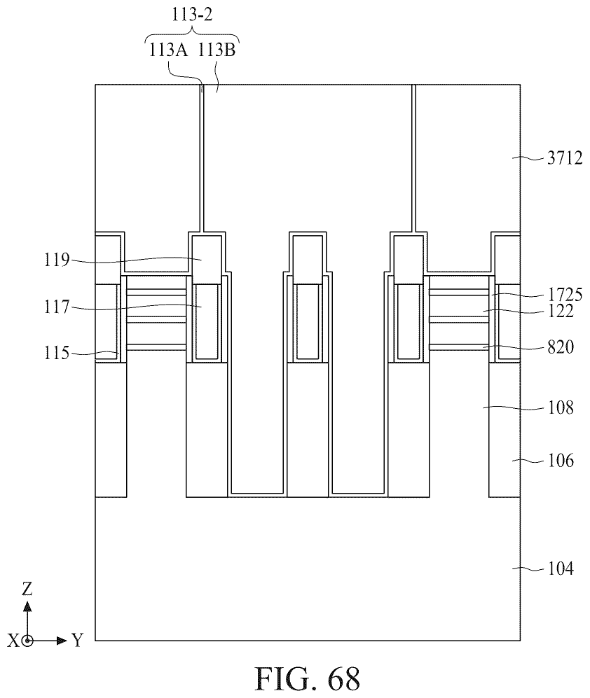

For illustrative purposes, the operations illustrated in FIG. 6 will be described with reference to the example fabrication process for fabricating semiconductor device 100 as illustrated in FIGS. 7-68. FIG. 7 illustrates a top-down view of semiconductor device 100 having a dielectric fin structure at various stages of its fabrication, in accordance with some embodiments. FIGS. 8-68 illustrate partial isometric and partial cross-sectional views of semiconductor device 100 having a dielectric fin structure at various stages of its fabrication, in accordance with some embodiments. FIGS. 11, 14, 17, 20, 23, 26, 29, 32, 35, 37, 40, 43, 46, 49, and 52 illustrate partial isometric views of semiconductor device 100 at various stages of its fabrication, in accordance with some embodiments. FIGS. 8, 12, 15, 18, 21, 24, 27, 30, 33, 36, 38, 41, 44, 47, 50, 53, 55, 57, 59, 61, 63, 65, and 67 illustrate partial cross-sectional views of semiconductor device 100 along an X-axis (e.g., line A-A as shown in FIG. 2) at various stages of its fabrication, in accordance with some embodiments. FIGS. 9, 10, 13, 16, 19, 22, 25, 28, 31, 34, 39, 42, 45, 48, 51, 54, 56, 58, 60, 62, 64, 66, and 68 illustrate partial cross-sectional views of semiconductor device 100 along a Y-axis (e.g., line B-B as shown in FIG. 2) at various stages of its fabrication, in accordance with some embodiments. Elements in FIGS. 7-68 with the same annotations as elements in FIGS. 1-5 are described above.

In referring to FIG. 6, method 600 begins with operation 610 and the process of forming a channel structure extending along a first direction on a substrate. For example, as shown in FIGS. 7-9, nanostructures 122 and 820 along an X-axis can be formed on substrate 104. In some embodiments, nanostructures 122 and 820 can be stacked in an alternate configuration. Sacrificial nanostructures 823 can be formed on nanostructures 122-3 and protected by a hard mask layer 722. In some embodiments, nanostructures 122 and 820 and sacrificial nanostructures 823 can be epitaxially grown on substrate 104 and subsequently patterned with hard mask layer 722 to form stacks of nanostructures 122 and 820. In some embodiments, nanostructures 122 and 820 and sacrificial nanostructures 823 can be in the form of nanosheets, nanowires, or nano-ribbons. In some embodiments, nanostructures 122 and 820 and sacrificial nanostructures 823 can include semiconductor materials similar to or different from substrate 104. In some embodiments, nanostructures 122 and 820 and sacrificial nanostructures 823 can include different semiconductor materials. In some embodiments, nanostructures 820 can include semiconductor materials with etching rates and/or etch selectivity higher than nanostructures 122 but lower than sacrificial nanostructures 823. For example, nanostructures 122 can include silicon and nanostructures 820 can include silicon germanium with a germanium atomic percent from about 10% to about 40%. Sacrificial nanostructures 823 can include silicon germanium with a germanium atomic percent from about 25% to about 60%. In some embodiments, nanostructures 122 and 820 can include silicon doped with different dopants to have different etching rates and/or etch selectivity and to minimize loss of nanostructures 122 during the sheet formation process of nanostructures 122.

Embodiments of nanostructures 122 and 820 and sacrificial nanostructures 823 disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures.

The formation of nanostructures 122 and 820 and sacrificial nanostructures 823 can be followed by the formation of STI regions 106 between adjacent stacks of nanostructures 122 and 820, as shown in FIG. 9-16. In some embodiments, as shown in FIG. 9, an oxide liner 105 can be conformally deposited on substrate 104, nanostructures 122 and 820, and sacrificial nanostructures 823 for protection in subsequent formation of STI regions 106. In some embodiments, oxide liner 105 can include silicon oxide or other suitable dielectric materials. In some embodiments, as shown in FIG. 10, a dielectric material 1006 can be deposited on oxide liner 105 over substrate 104, nanostructures 122 and 820, and sacrificial nanostructures 823. In some embodiments, as shown in FIGS. 11-13, dielectric material 1006 can be polished by a chemical mechanical polishing (CMP) process to form STI regions 106 between adjacent stacks of nanostructures 122 and 820. The CMP process can remove hard mask layer 722 and planarize top surfaces of STI regions 106 and sacrificial nanostructures 823. In some embodiments, as shown in FIGS. 14-16, STI regions 106 can be recessed and top surfaces of STI regions 106 can be below nanostructures 122 and 820.

The formation of STI regions 106 can be followed by the formation of cladding layer 1725. For example, as shown in FIGS. 17-19, cladding layer 1725 can be conformally deposited on STI regions 106, nanostructures 122 and 820, and sacrificial nanostructures 823. In some embodiments, cladding layer 1725 can include semiconductor materials with etching rates and/or etch selectivity similar to nanostructures 820 and lower than sacrificial nanostructures 823. In some embodiments, cladding layer 1725 can include silicon germanium with a germanium atomic percent from about 10% to about 40%. In some embodiments, cladding layer 1725 on top surfaces of STI regions 106 and sacrificial nanostructures 823 can be removed by a directional etching process, as shown in FIGS. 20-22. After the directional etching process, cladding layer 1725 can remain on sidewalls of nanostructures 122 and 820 and sacrificial nanostructures 823.

The formation of cladding layer 1725 can be followed by the formation of isolation layer 117. For example, as shown in FIGS. 23-28, isolation layer 117 can be formed on STI regions 106 between stacks of nanostructures 122 and 820. In some embodiments, as shown in FIGS. 23-25, protection layer 115 can be conformally deposited on top surfaces of STI regions 106 and sacrificial nanostructures 823 and sidewall surfaces of cladding layer 1725. In some embodiments, protection layer 115 can include silicon carbonitride or other suitable dielectric materials to protect cladding layer 1725 and sacrificial nanostructures 823 in subsequent processes. In some embodiments, an oxide material 2317 can be deposited on protection layer 115 to fill the openings between stacks of nanostructures 122 and 820. In some embodiments, oxide material 2317 can include silicon oxide or other suitable oxide materials. In some embodiments, as shown in FIGS. 26-28, oxide material 2317 can be planarized by a CMP process and recessed by an etching process to form isolation layer 117. In some embodiments, a top surface of isolation layer 117 can be above the top surfaces of top nanostructures 122-3 for lower device parasitic capacitance.

Referring to FIG. 6, in operation 620, a dielectric fin structure is formed on the substrate and adjacent to the channel structure. The dielectric fin structure includes a stiff dielectric material and extends along a second direction parallel to the first direction. For example, as shown in FIGS. 29-31, dielectric fin structures 119 can be formed on isolation layer 117 over STI regions 106 and between adjacent stacks of nanostructures 122 and 820. In some embodiments, dielectric fin structures 119 can include a stiff dielectric material. In some embodiments, the stiff dielectric material can have a Young's modulus greater than silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon nitride, silicon carbide, silicon carbonitride, silicon oxycarbonitride, silicon, aluminum oxide, or other suitable lower k dielectric materials. In some embodiments, dielectric fin structures 119 can have a higher etch resistivity to remain after various etching processes. In some embodiments, the stiff dielectric material in dielectric fin structures 119 can have a lower etching rate than the semiconductor material in nanostructures 122. As a result, dielectric fin structures 119 can remain after the etching from the CPODE and CMODE processes. In some embodiments, dielectric fin structures 119 can extend along an X-axis parallel to nanostructures 122. In some embodiments, as shown in FIG. 29, dielectric fin structures 119 and nanostructures 122 can be disposed over substrate 104 in an alternate configuration. In some embodiments, the bottom surface of dielectric fin structures 119 can be above the top surfaces of top nanostructures 122-3. In some embodiments, dielectric fin structures 119 can reduce the deformation of substrate 104 and minimize the LDE effect of semiconductor device 100 on substrate 104. As a result, dielectric fin structures 119 can reduce leakage current caused by the iso-dense depth loading effect, minimize damage to S/D epitaxial structures caused by the iso-dense critical dimension loading effect, and reduce Vₜ shift of semiconductor device 100 caused by gate deformation.

Referring to FIG. 6, in operation 630, a sacrificial gate structure can be formed on the channel structure and the dielectric fin structure. For example, as shown in FIGS. 32-42, sacrificial gate structures 3712 can be formed on nanostructures 122 and dielectric fin structures 119. In some embodiments, the formation of sacrificial gate structures 3712 can include removal of sacrificial nanostructures 823, conformal deposition of liner 3524, and deposition of sacrificial gate structures 3712. In some embodiments, an etching process can remove sacrificial nanostructures 823. The etching process may not remove dielectric fin structures 119 because of the etching selectivity between dielectric fin structures 119 and sacrificial nanostructures 823. In some embodiments, liner 3524 can be conformally deposited on nanostructures 122 and dielectric fin structures 119. Liner 3524 can include silicon oxide or other suitable dielectric materials. In some embodiments, sacrificial gate structures 3712 can be deposited on liner 3524 over nanostructures 122 and dielectric fin structures 119. In some embodiments, as shown in FIGS. 40-42, sacrificial gate structures 3712 can be patterned with nitride hard mask layer 4032 and oxide hard mask layer 4034. A spacer layer 4014 can be conformally deposited on sacrificial gate structures 3712, nitride hard mask layer 4032, oxide hard mask layer 4034, nanostructures 122, and dielectric fin structures 119.

The formation of sacrificial gate structures 3712 can be followed by the formation of S/D structures 110, as shown in FIGS. 43-51. The formation of S/D structures 110 can include the removal of a portion of nanostructures 122 and 820, the formation of inner spacers 121, and the epitaxial growth of S/D structures 110. In some embodiments, as shown in FIGS. 43-45, a directional etching process can remove a portion of nanostructures 122 and 820 to form recesses 4510 on each side of sacrificial gate structures 3712. A lateral etching process can remove end portions of nanostructures 820 to form recesses 4521 between nanostructures 122. In some embodiments, as shown in FIGS. 46-48, inner spacers 121 can be formed in recesses 4521. In some embodiments, the formation of inner spacers 121 can include a blanket deposition of a spacer layer followed by an etching process to remove the spacer layer on sidewalls and top surfaces of sacrificial gate structures 3712 and nanostructures 122 and 820. In some embodiments, as shown in FIGS. 49-51, S/D structures 110 can be epitaxially grown on fin structures 108 and in contact with nanostructures 122. In some embodiments, S/D structures 110 can be formed between adjacent stacks of protection layer 115, isolation layer 117, and dielectric fin structures 119. In some embodiments, S/D structures 110 can be in contact with protection layer 115. In some embodiments, S/D structures 110 can be in-situ doped with n-type or p-type dopants during the epitaxial growth processes.

The formation of S/D structures 110 can be followed by the formation of ESL 116 and ILD layer 118 on S/D structures 110, dielectric fin structures 119, and gate spacers 114, as shown in FIGS. 52-56. In some embodiments, ESL 116 can be conformally deposited on S/D structures 110, dielectric fin structures 119, and gate spacers 114. In some embodiments, ILD layer 118 can be blanket deposited on ESL 116. A subsequent CMP process can planarize top surfaces of gate spacers 114, ESL 116, ILD layer 118, and sacrificial gate structures 3712. In some embodiments, ILD layer 118 can be recessed between sacrificial gate structures 3712. Hard mask layer 5236 can be deposited in the recesses and on sacrificial gate structures 3712, as shown in FIGS. 52-56. In some embodiments, hard mask layer 5236 can include silicon nitride or other suitable dielectric material. In some embodiments, as shown in FIGS. 53 and 54, S/D structures 110 can include multiple epitaxial layers having different material compositions and doping concentrations. In some embodiments, as shown in FIGS. 55 and 56, S/D structures 110 can extend further into substrate 104.

Referring to FIG. 6, in operation 640, an isolation structure is formed extending through the sacrificial gate structure and the channel structure and in contact with the dielectric fin structure. For example, as shown in FIGS. 58-68, trench isolation structures 113-2 can be formed on substrate 104 extending through sacrificial gate structures 3712 and nanostructures 122. Trench isolation structures 113-2 can be in contact with dielectric fin structures 119. In some embodiments, a stack of bottom layer 5738, middle layer 5740, and photoresist 5742 can be deposited on hard mask layer 5236. In some embodiments, openings 5713 can be patterned in photoresist 5742 above sacrificial gate structures 3712, as shown in FIGS. 57 and 58. After the patterning process, openings 5713 can be formed in hard mask layer 5236 by a dry etching process, as shown in FIGS. 59 and 60.

In some embodiments, a dry etching process can remove sacrificial gate structures 3712 and extend openings 5713 through sacrificial gate structures 3712, as shown in FIGS. 61 and 62. In some embodiments, the etching of sacrificial gate structures 3712 can be directional and self-aligned. The etchants can include hydrogen bromide-based plasma with an addition of oxygen or carbon dioxide. In some embodiments, the hydrogen bromide-based plasma can be a high density plasma generated by an inductively coupled plasma or resonant antenna plasma source with a radio-frequency (RF) power generator. In some embodiments, the RF power generator can use an alternate current (AC) operating at a frequency of multiples of about 13.56 MHz. In some embodiments, the RF power generator can provide a source power from about 0 W to about 2500 W to generate plasma. In some embodiments, a RF bias power can range from about 0 W to about 2000 W. In some embodiments, a pulse plasma etch with a duty cycle from about 5% to about 95% can be used in the etching process. In some embodiments, the plasma etching process can use a bias power with zero source power to increase the directionality of the etching process. In some embodiments, the etching process chamber can be operated at a temperature from about 10° C. to about 200° C. under a pressure ranging from about 1 mTorr to about 200 mTorr.

In some embodiments, to increase etching selectivity between sacrificial gate structures 3712 and hard mask layer 5236, a polymer layer can be formed on hard mask layer 5236 with a methane-based deposition process. In some embodiments, oxides (e.g., silicon oxide) can be formed during the dry etching process to improve the self-aligned etching process. In some embodiments, the oxides can be formed by silicon tetrachloride, oxygen, and hydrogen bromide. In some embodiments, a wet clean process can be performed to remove the oxides on nanostructures 122 and dielectric fin structures 119 formed during the dry etching process. In some embodiments, the wet clean process can include etchants of carbon tetrafluoride (CF₄), trifluoromethane (CHF₃), difluoromethane (CH₂F₂), fluoromethane (CH₃F), and hexafluorobutadiene (C₄F₆). In some embodiments, as shown in FIGS. 63 and 64, additional dry etching processes can extend openings 5713 through nanostructures 122 into substrate 104.

In some embodiments, as shown in FIGS. 65-68, trench isolation structures 113-2 can be formed in openings 5713. In some embodiments, trench isolation structures 113-2 can include liner 113A and dielectric fill 113B. Liner 113A can be conformally deposited on hard mask layer 5236, substrate 104, and sidewalls of STI regions 106, isolation layer 117, dielectric fin structures 119, gate spacers 114, and sacrificial gate structures 3712. Dielectric fill 113B can be blanket deposited on liner 113A and can fill openings 5713, as shown in FIGS. 65 and 66. In some embodiments, a CMP process can planarize top surfaces of gate spacers 114, ESL 116, hard mask layer 5236, trench isolation structures 113-2, and sacrificial gate structures 3712.

In some embodiments, trench isolation structures 113-2 can include silicon oxide, silicon nitride, silicon oxynitride, silicon oxycarbonitride, or other suitable dielectric materials. In some embodiments, trench isolation structures 113-2 can extend through sacrificial gate structures 3712, nanostructures 122, STI regions 106, and fin structures 108 into substrate 104. In some embodiments, trench isolation structures 113-2 can be formed by the CPODE process to reduce leakage current flowing through S/D structures 110, nanostructures 122, and substrate 104.

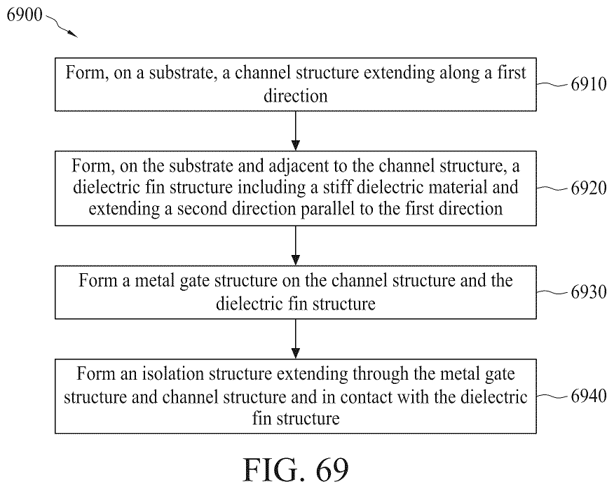

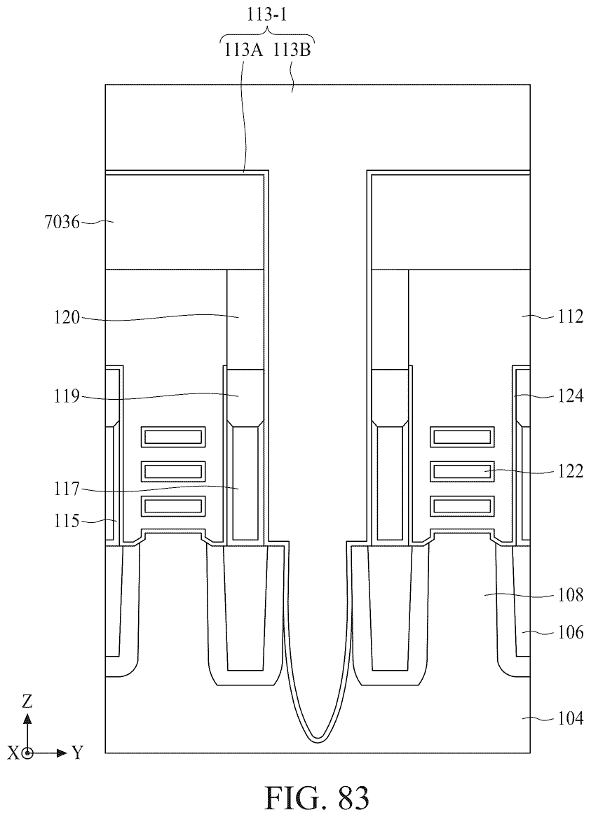

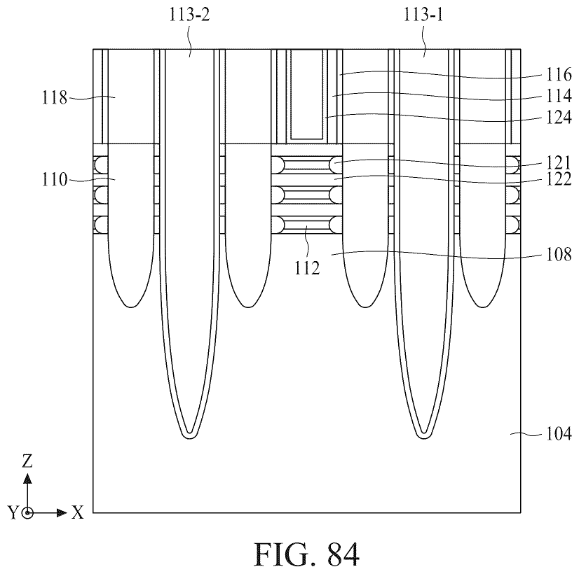

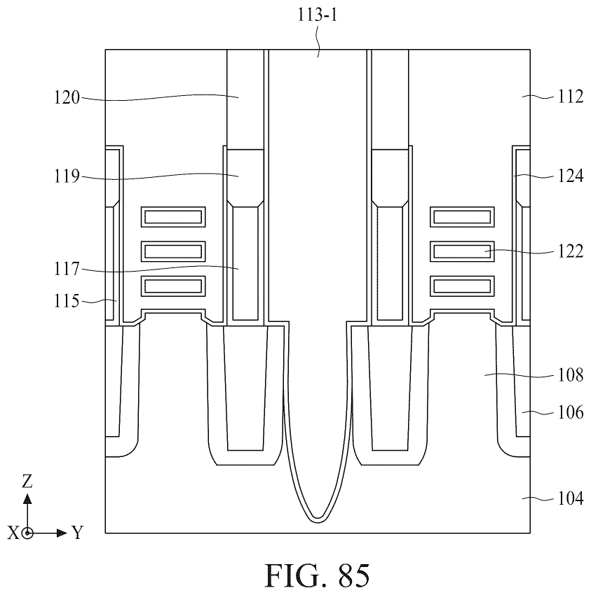

Referring to FIG. 6, in operation 650, the sacrificial gate structure can be replaced with a metal gate structure. For example, as shown in FIGS. 2-5, sacrificial gate structures 3712 can be replaced with metal gate structures 112. In some embodiments, the replacement of gate structures 112 can include removal of sacrificial gate structures 3712, removal of nanostructures 820, and deposition of gate structures 112, the processes of which are not described in detail for clarity. In some embodiments, trench isolation structures 113 can be formed after the replacement of gate structures 112, as described in FIGS. 69-85.

FIG. 69 is a flow diagram of another method 6900 for fabricating semiconductor device 100 having a dielectric fin structure, in accordance with some embodiments. Method 6900 may not be limited to nanostructure transistor devices and can be applicable to other devices that would benefit from the dielectric fin structure. Additional fabrication operations may be performed between various operations of method 6900 and may be omitted merely for clarity and ease of description. Additional processes can be provided before, during, and/or after method 6900; one or more of these additional processes are briefly described herein. Moreover, not all operations may be needed to perform the disclosure provided herein. Additionally, some of the operations may be performed simultaneously or in a different order than shown in FIG. 69. In some embodiments, one or more other operations may be performed in addition to or in place of the presently-described operations.

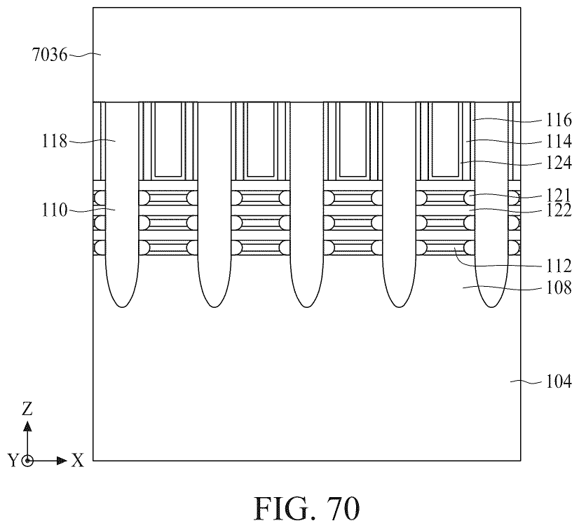

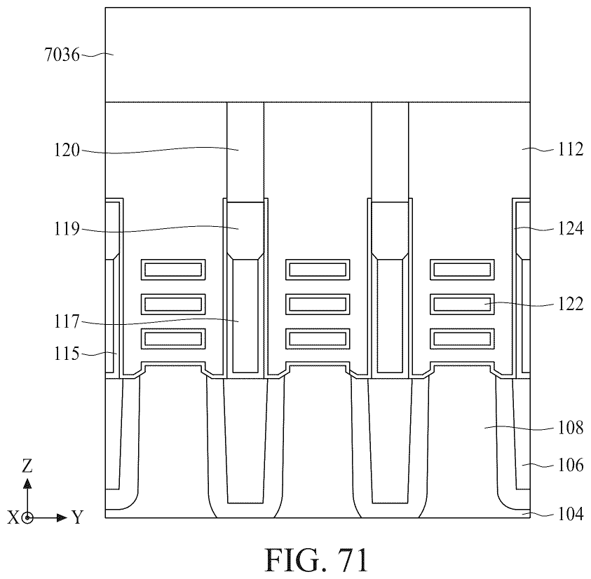

For illustrative purposes, the operations illustrated in FIG. 69 will be described with reference to the example fabrication process for fabricating semiconductor device 100 as illustrated in FIGS. 7-56 and 70-85. FIGS. 7-56 are described above. FIGS. 70-85 illustrate partial cross-sectional views of semiconductor device 100 having a dielectric fin structure at various stages of its fabrication using another method, in accordance with some embodiments. FIGS. 70, 72, 74, 76, 78, 80, 82, and 84 illustrate partial cross-sectional views of semiconductor device 100 along an X-axis (e.g., line A-A as shown in FIG. 2) at various stages of its fabrication using another method, in accordance with some embodiments. FIGS. 71, 73, 75, 77, 79, 81, 83, and 85 illustrate partial cross-sectional views of semiconductor device 100 along a Y-axis (e.g., line C-C as shown in FIG. 2) at various stages of its fabrication using another method, in accordance with some embodiments. Elements in FIGS. 70-85 with the same annotations as elements in FIGS. 1-5 are described above.

In referring to FIG. 69, method 6900 begins with operation 6910 and the process of forming a channel structure extending along a first direction on a substrate. In some embodiments, operation 6910 can be similar to operation 610 as described above. For example, as shown in FIGS. 7-9, nanostructures 122 and 820 along an X-axis can be formed on substrate 104. In some embodiments, the formation of nanostructures 122 and 820 can be followed by the formation of STI regions 106 between adjacent stacks of nanostructures 122 and 820, as shown in FIG. 9-16. In some embodiments, the formation of STI regions 106 can be followed by the formation of cladding layer 1725, as shown in FIGS. 17-19. In some embodiments, the formation of cladding layer 1725 can be followed by the formation of isolation layer 117, as shown in FIGS. 23-28.

Referring to FIG. 69, in operation 6920, a dielectric fin structure is formed on the substrate and adjacent to the channel structure. The dielectric fin structure includes a stiff dielectric material and extends along a second direction parallel to the first direction. In some embodiments, operation 6920 can be similar to operation 620 as described above. For example, as shown in FIGS. 29-31, dielectric fin structures 119 can be formed on isolation layer 117 over STI regions 106 and between adjacent stacks of nanostructures 122 and 820. In some embodiments, dielectric fin structures 119 can extend along an X-axis parallel to nanostructures 122.

Referring to FIG. 69, in operation 6930, a metal gate structure is formed on the channel structure and the dielectric fin structures. For example, as shown in FIGS. 70 and 71, gate structures 112 can be formed on nanostructures 122 and dielectric fin structures 119. In some embodiments, the formation of gate structures 112 can include removal of sacrificial gate structures 3712 shown in FIG. 52, removal of nanostructures 820 shown in FIG. 52, and deposition of one or more work function metal layers and a metal fill around nanostructures 122. In some embodiments, gate isolation structures 120 can be formed in gate structures 112 and on dielectric fin structures 119 to separate gate structures 112 into multiple portions. In some embodiments, hard mask layer 7036 can be deposited on gate structures 112, gate spacers 114, ESL 116, ILD layer 118, and gate isolation structures 120.

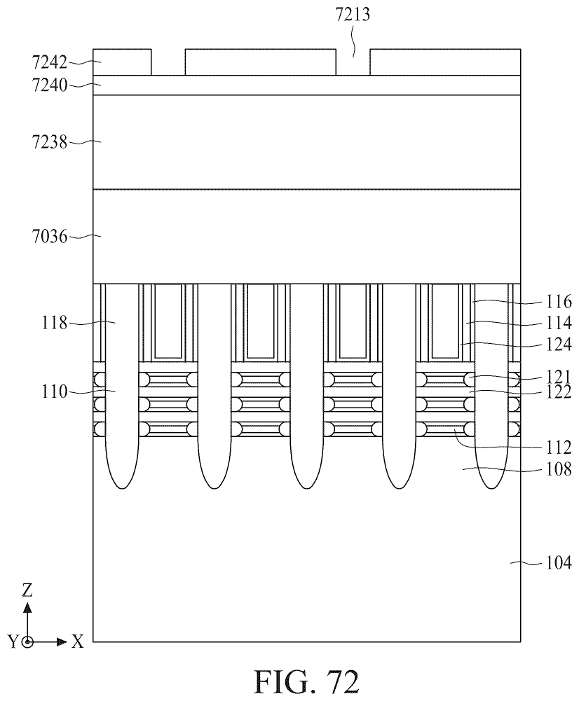

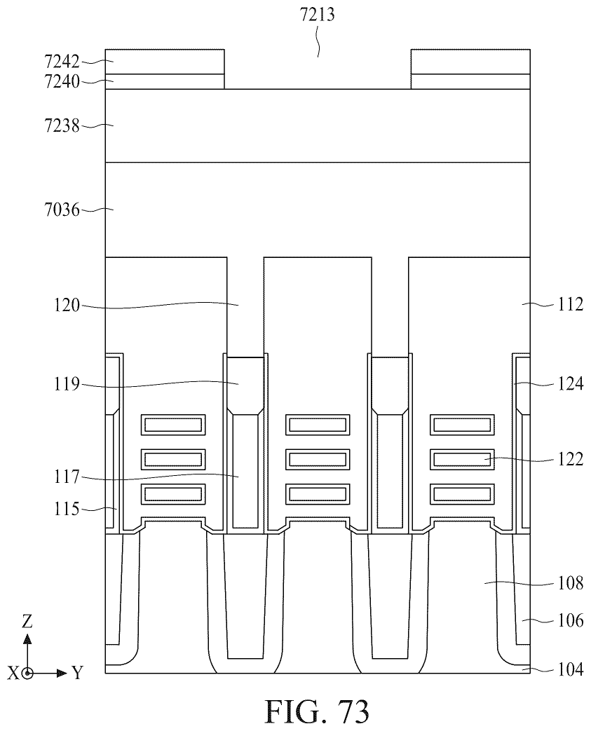

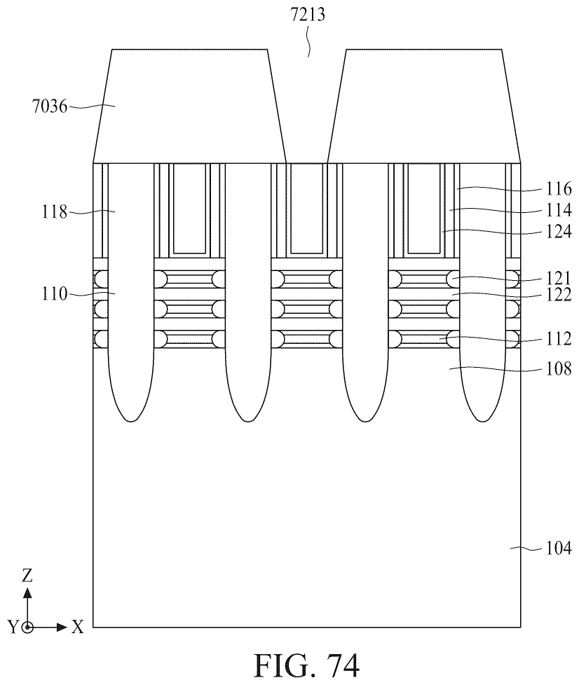

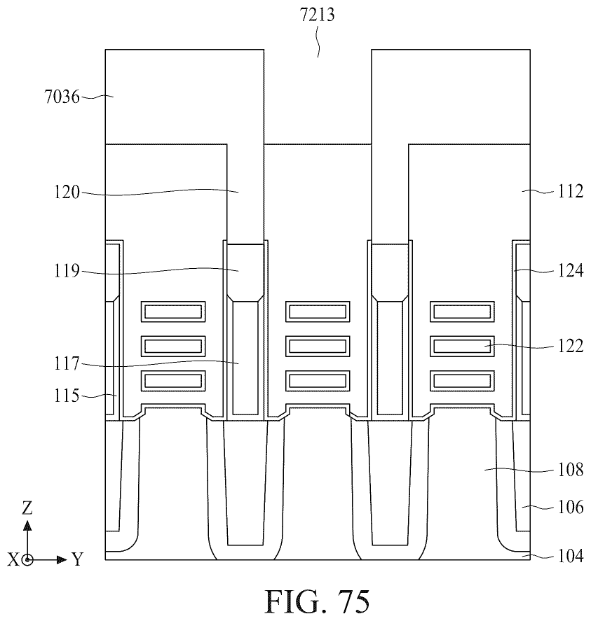

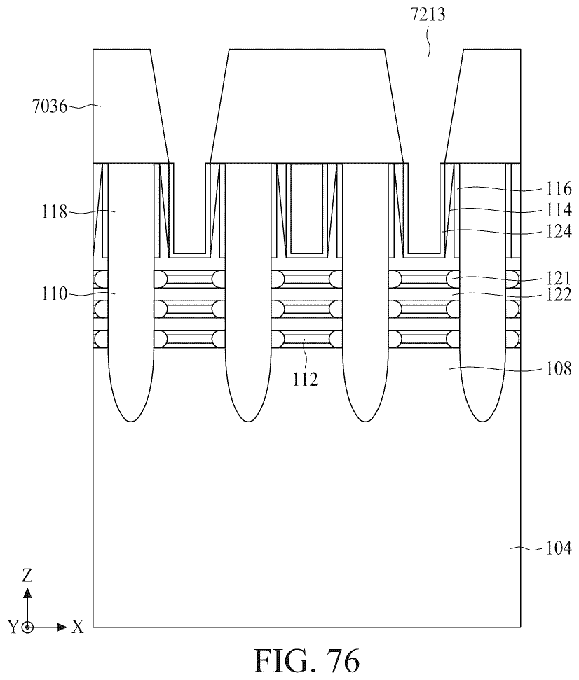

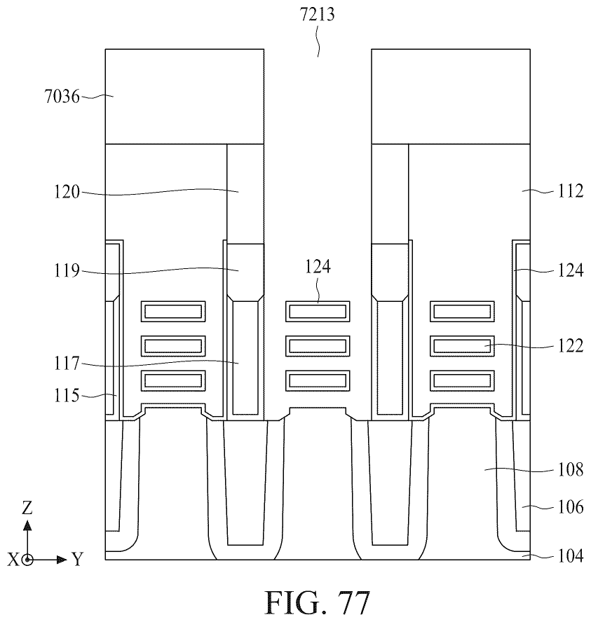

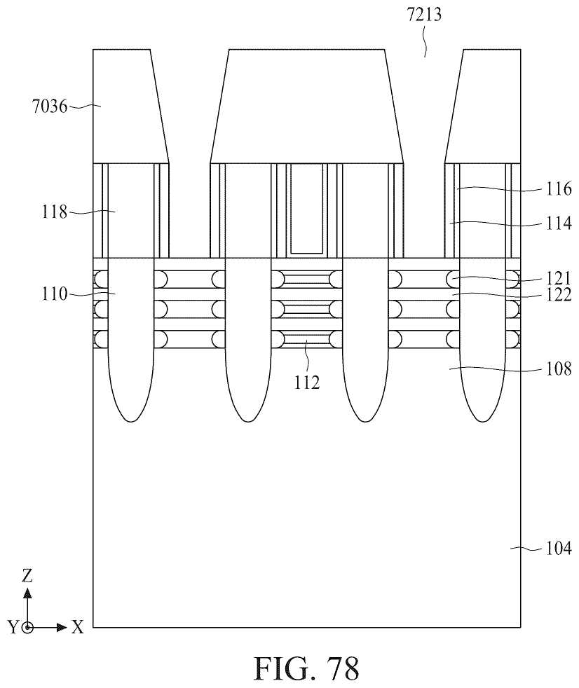

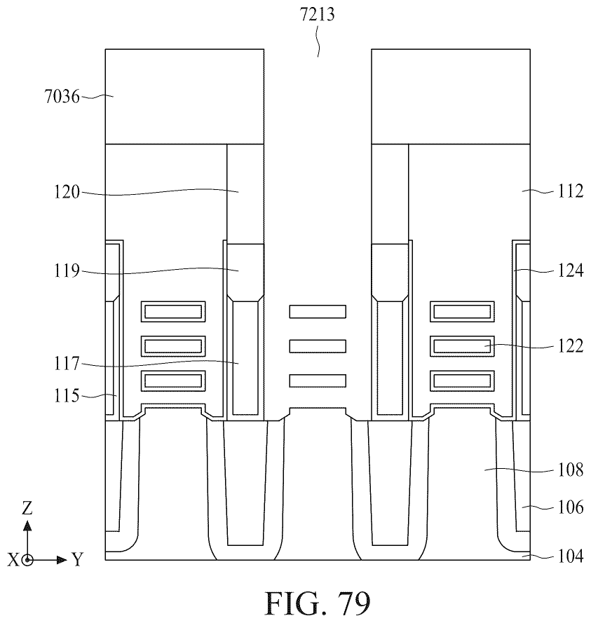

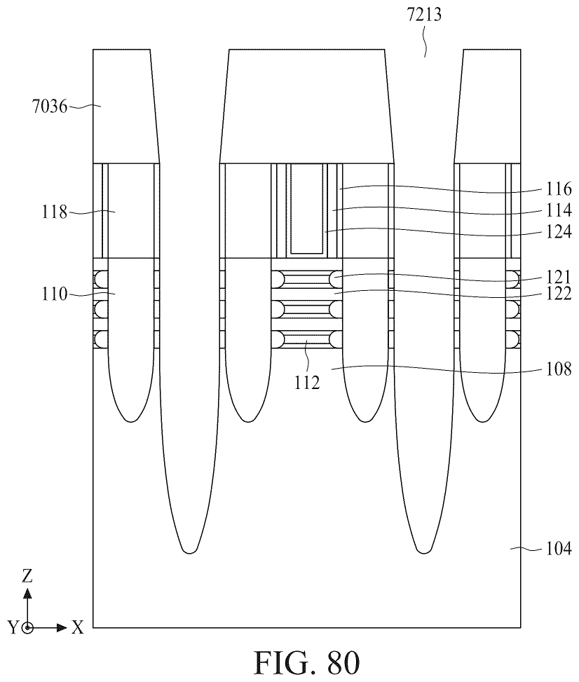

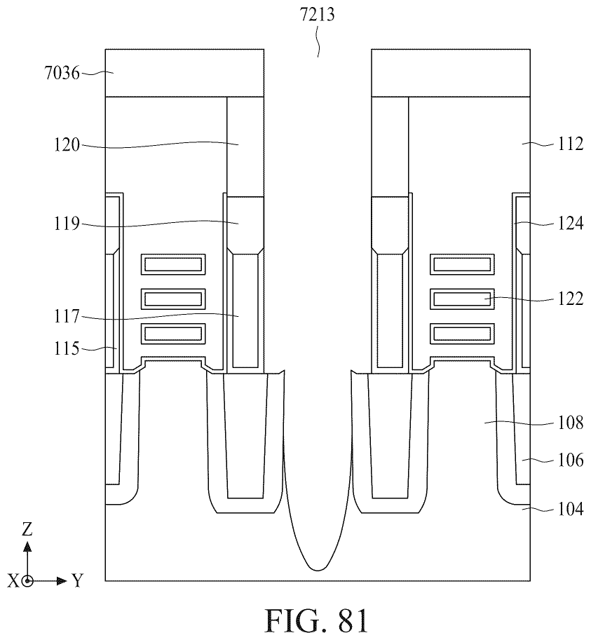

Referring to FIG. 69, in operation 6940, an isolation structure is formed extending through the metal gate structure and channel structure and in contact with the dielectric fin structure. For example, as shown in FIGS. 72-85, trench isolation structures 113-1 and 113-2 can be formed on substrate 104 extending through gate structures 112 and nanostructures 122 and in contact with dielectric fin structures 119. In some embodiments, a stack of bottom layer 7238, middle layer 7240, and photoresist 7242 can be deposited on hard mask layer 7036. In some embodiments, openings 7213 can be patterned in photoresist 7242 above gate structures 112, as shown in FIGS. 72 and 73. After the patterning process, openings 7213 can be formed in hard mask layer 7036 by a dry etching process, as shown in FIGS. 74 and 75. In some embodiments, a high selective etching process can remove gate structures 112 and extend openings 7213 through gate structures 112, as shown in FIGS. 76 and 77. In some embodiments, the high selective etching process can include a dry etching process or a wet etching process. After the selective etching process, gate structures 112 can be removed while gate dielectric layer 124 can remain on nanostructures 122. In some embodiments, a wet clean process after each of the dry etching process or wet etching process can remove any residues formed during the etching processes. In some embodiments, as shown in FIGS. 78 and 79, another selective etching process can remove gate dielectric layer 124 from nanostructures 122. In some embodiments, the selective etching process can include a dry etching process or a wet etching process. In some embodiments, as shown in FIGS. 80 and 81, additional dry etching processes can remove nanostructures 122 and extend openings 7213 through nanostructures 122 into substrate 104.

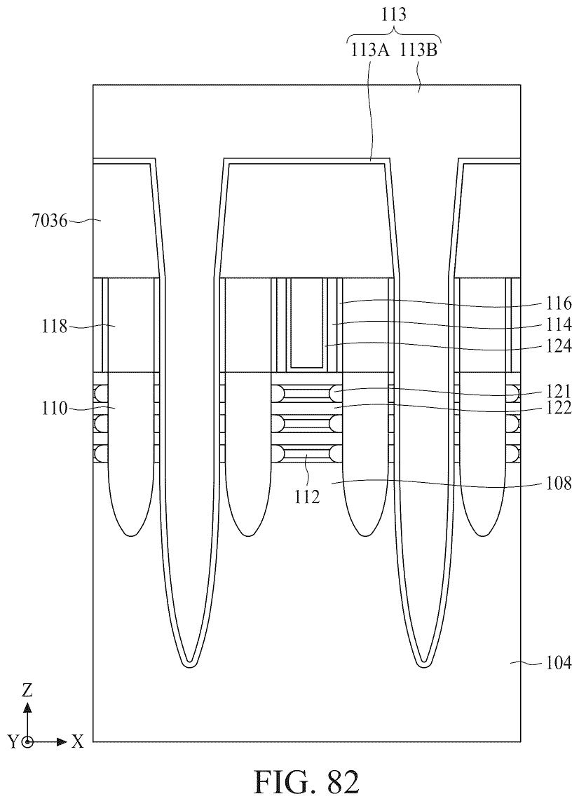

In some embodiments, as shown in FIGS. 82-85, trench isolation structures 113-1 and 113-2 can be formed in openings 7213. In some embodiments, trench isolation structures 113-1 and 113-2 can include liner 113A and dielectric fill 113B. Liner 113A can be conformally deposited on hard mask layer 7036, substrate 104, and sidewalls of STI regions 106, isolation layer 117, dielectric fin structures 119, gate spacers 114, and gate isolation structures 120. Dielectric fill 113B can be blanket deposited on liner 113A and can fill openings 7213, as shown in FIGS. 82 and 83. In some embodiments, a CMP process can planarize top surfaces of gate spacers 114, ESL 116, ILD layer 118, trench isolation structures 113-1 and 113-2, gate isolation structures 120, and gate structures 112.

In some embodiments, trench isolation structures 113-1 and 113-2 can include silicon oxide, silicon nitride, silicon oxynitride, silicon oxycarbonitride, or other suitable dielectric materials. In some embodiments, trench isolation structures 113-1 and 113-2 can extend through gate structures 112, nanostructures 122, STI regions 106, and fin structures 108 into substrate 104. In some embodiments, trench isolation structures 113-1 and 113-2 can be formed by the CMODE processes to reduce leakage current flowing through S/D structures 110, nanostructures 122, and substrate 104.

Various embodiments of the present disclosure provide methods for forming dielectric fin structures 119 in semiconductor device 100. In some embodiments, nanostructures 122 extending along a first direction can be formed on substrate 104. Dielectric fin structures 119 can be formed on substrate 104 and adjacent to nanostructures 122. In some embodiments, dielectric fin structures 119 can include a stiff dielectric material and extend along a second direction parallel to the first direction. In some embodiments, the stiff dielectric material can have a Young's modulus greater than silicon oxide. In some embodiments, the stiff dielectric material can have a Young's modulus greater than about 75 GPa. Gate structures 112 can be formed on nanostructures 122 and dielectric fin structures 119. Trench isolation structures 113 can be formed on gate structures 112 and can extend through gate structures 112 and nanostructures 122. In some embodiments, trench isolation structures 113 can be in contact with dielectric fin structures 119. In some embodiments, trench isolation structures 113 can be formed by the CPODE or CMODE process. In some embodiments, dielectric fin structures 119 can reduce the deformation of substrate 104 and minimize the LDE effect of the semiconductor devices on substrates 104. Accordingly, dielectric fin structures 119 can reduce the device leakage current, minimize damage to S/D structures 110, and reduce Vₜ shift of the semiconductor devices on substrate 104.

In some embodiments, a semiconductor structure includes a channel structure on a substrate. The channel structure extends along a first direction. The semiconductor structure further includes a dielectric fin structure on the substrate and adjacent to the channel structure. The dielectric fin structure includes a stiff dielectric material and extends along a second direction parallel to the first direction. The semiconductor structure further includes an isolation structure extending through the channel structure. The isolation structure is in contact with the dielectric fin structure.

In some embodiments, a semiconductor device includes multiple channel structures on a substrate and multiple dielectric fin structures including a stiff dielectric material on the substrate. The multiple channel structures and the multiple dielectric fin structures are arranged in an alternate configuration. The semiconductor device further includes a gate structure surrounding the multiple channel structures and the multiple dielectric fin structures and an isolation structure extending through the gate structure and at least one of the multiple channel structures. The isolation structure is in contact with the at least one of the multiple dielectric fin structures.

In some embodiments, a method includes forming a channel structure on a substrate and forming a dielectric fin structure on the substrate and adjacent to the channel structure. The channel structure extends along a first direction. The dielectric fin structure includes a stiff dielectric material and extends along a second direction parallel to the first direction. The method further includes forming an isolation structure extending through the channel structure. The isolation structure is in contact with the dielectric fin structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first and second channel structures on a substrate;
a dielectric fin structure on the substrate and between the first and second channel structures, wherein the dielectric fin structure comprises a dielectric material and a top surface of the dielectric fin structure is above top surfaces of the first and second channel structures; and
an isolation structure extending into the substrate, wherein the isolation structure is in contact with the dielectric fin structure.

2. The semiconductor structure of claim 1, wherein the dielectric fin structure is on a top surface of an isolation layer and the dielectric material has a Young's modulus greater than about 75 GPa.

3. The semiconductor structure of claim 1, further comprising a first gate structure wrapped around the first channel structure and a second gate structure wrapped around the second channel structure, wherein the isolation structure is between the first gate structure and the second gate structure.

4. The semiconductor structure of claim 3, wherein the top surface of the dielectric fin structure is below top surfaces of the first and second gate structures.

5. The semiconductor structure of claim 3, wherein a ratio of a height of the isolation structure to a height of the first gate structure ranges from about 0.15 to about 0.3.

6. The semiconductor structure of claim 1, wherein the top surface of the dielectric fin structure is below a top surface of the isolation structure.

7. The semiconductor structure of claim 1, wherein a bottom surface of the dielectric fin structure is at a same level or above the top surfaces of the first and second channel structures.

8. The semiconductor structure of claim 1, wherein the dielectric fin structure is surrounded by the isolation structure.

9. The semiconductor structure of claim 1, wherein the isolation structure comprises a liner in contact with the dielectric fin structure and a dielectric fill on the liner.

10. A semiconductor device, comprising:
a plurality of channel structures on a substrate extending along a first direction;
a plurality of dielectric fin structures on the substrate and extending along the first direction, wherein the plurality of channel structures and the plurality of dielectric fin structures are arranged in an alternate configuration;
a gate structure on the plurality of channel structures and the plurality of dielectric fin structures, wherein the gate structure extends along a second direction different from the first direction; and
an isolation structure extending through the gate structure to separate the gate structure, wherein the isolation structure is between two of the plurality of dielectric fin structures.

11. The semiconductor device of claim 10, wherein the plurality of dielectric fin structures are on a top surface of an isolation layer and comprises a high-k dielectric material.

12. The semiconductor device of claim 10, wherein top surfaces of the plurality of dielectric fin structures are below a top surface of the gate structure.

13. The semiconductor device of claim 10, wherein top surfaces of the gate structure and the isolation structure are coplanar.

14. The semiconductor device of claim 10, wherein bottom surfaces of the plurality of dielectric fin structures are at a same level as or above top surfaces of the plurality of channel structures.

15. The semiconductor device of claim 10, wherein the isolation structure extends through at least one of the plurality of channel structures into the substrate.

16. A method, comprising:
forming first and second channel structures on a substrate;
forming a dielectric fin structure on the substrate and between the first and second channel structures, wherein the dielectric fin structure comprises a dielectric material and a top surface of the dielectric fin structure is above top surfaces of the first and second channel structures; and
forming an isolation structure extending into the substrate, wherein the isolation structure is in contact with the dielectric fin structure.

17. The method of claim 16, further comprising forming a first gate structure wrapped around the first channel structure and a second gate structure wrapped around the second channel structure, wherein the isolation structure is between the first gate structure and the second gate structure.

18. The method of claim 16, wherein forming the dielectric fin structure comprises:
forming an isolation layer on the first and second channel structures;
etching the isolation layer to form an opening between the first and second channel structures, wherein a bottom surface of the opening is at a same level as or above the top surfaces of the first and second channel structures; and
filling the opening with the dielectric material, wherein the dielectric material has a Young's modulus greater than about 75 GPa.

19. The method of claim 16, wherein forming the isolation structure comprises:
forming a sacrificial gate structure on the first and second channel structures and the dielectric fin structure;
etching through the sacrificial gate structure and at least one of the first and second channel structures to form an opening;
depositing an additional dielectric material in the opening, wherein the additional dielectric material is in contact with the dielectric fin structure; and
replacing the sacrificial gate structure with a metal gate structure.

20. The method of claim 16, wherein forming the isolation structure comprises:
forming a metal gate structure on the first and second channel structures and the dielectric fin structure;
etching through the metal gate structure and at least one of the first and second channel structures to form an opening; and
depositing an additional dielectric material in the opening, wherein the additional dielectric material is in contact with the dielectric fin structure.
